(19) United States
(12) Patent Application Publication
(10) Pub. No.: US 2024/0324174 A1
(43) Pub. Date: Sep. 26, 2024

(54) SEMICONDUCTOR MEMORY DEVICE

(71) Applicant: Kioxia Corporation, Tokyo (JP)

(72) Inventors: Takafumi MASUDA, Kawasaki Kanagawa (JP); Mutsumi OKAJIMA, Yokkaichi Mie (JP); Nobuyoshi SAITO, Ota Tokyo (JP); Keiji IKEDA, Kawasaki Kanagawa (JP)

(73) Assignee: Kioxia Corporation, Tokyo (JP)

(21) Appl. No.: 18/605,986

(22) Filed: Mar. 15, 2024

(30) Foreign Application Priority Data
Mar. 23, 2023 (JP) 2023-047353

(51) Int. Cl. H10B 12/00

(52) U.S. Cl. CPC H10B 12/30; H10B 12/03; H10B 12/05

(57) ABSTRACT

A semiconductor memory device includes memory layers arranged in a first direction and a via-wiring extending in the first direction. The plurality of memory layers each include a semiconductor layer electrically connected to the via-wiring, a gate electrode opposed to surfaces of the semiconductor layer in the first direction, a memory portion disposed on one side in a second direction with respect to the semiconductor layer, a wiring disposed on the other side in the second direction with respect to the semiconductor layer, and a connection wiring connected to the gate electrode and the wiring. The connection wiring includes a first part extending in the second direction along a side surface of the gate electrode in the third direction and a second part continuous with the first part, extending in the third direction along a side surface of the wiring in the second direction.

### CROSS-REFERENCE TO RELATED APPLICATIONS

This application is based upon and claims the benefit of Japanese Patent Application No. 2023-047353, filed on Mar. 23, 2023, the entire contents of which are incorporated herein by reference.

### BACKGROUND

### Field

Embodiments described herein relate generally to a semiconductor memory device.

### Description of the Related Art

In accordance with high integration of a semiconductor memory device, an examination for converting the semiconductor memory device into a three-dimensional form has been in progress.

### BRIEF DESCRIPTION OF THE DRAWINGS

FIG. 1 is a schematic circuit diagram illustrating a configuration of a part of a semiconductor memory device according to a first embodiment;

FIG. 2 is a schematic perspective view illustrating a configuration of a part of the semiconductor memory device;

FIG. 3 is a schematic cross-sectional view illustrating a configuration of a part of the semiconductor memory device;

FIG. 4 is a schematic perspective view illustrating a configuration of a part of the semiconductor memory device;

FIG. 5 is a schematic cross-sectional view illustrating a configuration of a part of the semiconductor memory device;

FIG. 6 is a schematic cross-sectional view illustrating a configuration of a part of the semiconductor memory device;

FIG. 7 is a schematic cross-sectional view illustrating a configuration of a part of the semiconductor memory device;

FIG. 8 is a schematic cross-sectional view illustrating a configuration of a part of the semiconductor memory device;

FIG. 9 is a schematic perspective view illustrating a configuration of a part of the semiconductor memory device;

FIG. 10 is a schematic cross-sectional view for describing a manufacturing method of the semiconductor memory device according to the first embodiment;

FIG. 11 is a schematic cross-sectional view for describing the manufacturing method;

FIG. 12 is a schematic cross-sectional view for describing the manufacturing method;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic cross-sectional view for describing the manufacturing method;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic cross-sectional view for describing the manufacturing method;

FIG. 52 is a schematic cross-sectional view for describing the manufacturing method;

FIG. 53 is a schematic cross-sectional view for describing the manufacturing method;

FIG. 54 is a schematic cross-sectional view for describing the manufacturing method;

FIG. 55 is a schematic cross-sectional view for describing the manufacturing method;

FIG. 56 is a schematic cross-sectional view for describing the manufacturing method;

FIG. 57 is a schematic cross-sectional view for describing the manufacturing method;

FIG. 58 is a schematic cross-sectional view for describing the manufacturing method;

FIG. 59 is a schematic cross-sectional view for describing the manufacturing method;

FIG. 60 is a schematic cross-sectional view for describing the manufacturing method;

FIG. 61 is a schematic cross-sectional view for describing the manufacturing method;

FIG. 62 is a schematic cross-sectional view for describing the manufacturing method;

FIG. 63 is a schematic cross-sectional view for describing the manufacturing method;

FIG. 64 is a schematic cross-sectional view for describing the manufacturing method;

FIG. 65 is a schematic cross-sectional view for describing the manufacturing method;

FIG. 66 is a schematic cross-sectional view for describing the manufacturing method;

FIG. 67 is a schematic cross-sectional view for describing the manufacturing method;

FIG. 68 is a schematic cross-sectional view for describing the manufacturing method;

FIG. 69 is a schematic cross-sectional view for describing the manufacturing method;

FIG. 70 is a schematic cross-sectional view for describing the manufacturing method;

FIG. 71 is a schematic cross-sectional view for describing the manufacturing method;

FIG. 72 is a schematic cross-sectional view for describing the manufacturing method;

FIG. 73 is a schematic cross-sectional view for describing the manufacturing method;

FIG. 74 is a schematic cross-sectional view for describing the manufacturing method;

FIG. 75 is a schematic cross-sectional view for describing the manufacturing method;

FIG. 76 is a schematic cross-sectional view for describing the manufacturing method;

FIG. 77 is a schematic cross-sectional view for describing the manufacturing method;

FIG. 78 is a schematic cross-sectional view for describing the manufacturing method;

FIG. 79 is a schematic cross-sectional view for describing the manufacturing method;

FIG. 80 is a schematic cross-sectional view for describing the manufacturing method;

FIG. 81 is a schematic cross-sectional view for describing the manufacturing method;

FIG. 82 is a schematic cross-sectional view for describing the manufacturing method;

FIG. 83 is a schematic cross-sectional view for describing the manufacturing method;

FIG. 84 is a schematic cross-sectional view for describing the manufacturing method;

FIG. 85 is a schematic cross-sectional view for describing the manufacturing method;

FIG. 86 is a schematic cross-sectional view for describing the manufacturing method;

FIG. 87 is a schematic cross-sectional view illustrating a configuration of a part of a semiconductor memory device according to a second embodiment;

FIG. 88 is a schematic cross-sectional view illustrating a configuration of a part of the semiconductor memory device according to the second embodiment;

FIG. 89 is a schematic cross-sectional view illustrating a configuration of a part of the semiconductor memory device according to the second embodiment;

FIG. 90 is a schematic cross-sectional view illustrating a configuration of a part of the semiconductor memory device according to the second embodiment;

FIG. 91 is a schematic cross-sectional view illustrating a configuration of a part of the semiconductor memory device according to the second embodiment;

FIG. 92 is a schematic cross-sectional view for describing a manufacturing method of a semiconductor memory device according to a third embodiment;

FIG. 93 is a schematic cross-sectional view for describing the manufacturing method of the semiconductor memory device according to the third embodiment;

FIG. 94 is a schematic cross-sectional view illustrating a configuration of a part of the semiconductor memory device according to the third embodiment;

FIG. 95 is a schematic cross-sectional view illustrating a configuration of a part of a semiconductor memory device according to a fourth embodiment;

FIG. 96 is a schematic cross-sectional view illustrating a configuration of a part of a semiconductor memory device according to a fifth embodiment;

FIG. 97 is a schematic cross-sectional view for describing a manufacturing method of a semiconductor memory device according to a sixth embodiment; and

FIG. 98 is a schematic X-Y cross-sectional view illustrating a configuration of a part of the semiconductor memory device according to the sixth embodiment.

### DETAILED DESCRIPTION

A semiconductor memory device according to one embodiment comprises a substrate, a plurality of memory layers arranged in a first direction intersecting with a surface of the substrate, and a first via-wiring extending in the first direction. The plurality of memory layers each include a first semiconductor layer electrically connected to the first via-wiring, a first gate electrode opposed to surfaces of the first semiconductor layer on one side and the other side in the first direction, a first memory portion disposed on one side in a second direction intersecting with the first direction with respect to the first semiconductor layer and electrically connected to the first semiconductor layer, a first wiring disposed on the other side in the second direction with respect to the first semiconductor layer, electrically connected to the first gate electrode, and extending in a third direction intersecting with the first direction and the second direction, and a connection wiring connected to the first gate electrode and the first wiring. The connection wiring includes a first part extending in the second direction along a side surface of the first gate electrode on one side in the third direction and connected to the side surface of the first gate electrode on the one side in the third direction and a second part continuous with the first part, extending in the third direction along a side surface of the first wiring on a first via-wiring side in the second direction, and connected to the side surface of the first wiring on the first via-wiring side in the second direction.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is electrically connected between” the second configuration and a third configuration, it may mean that the first configuration, the second configuration, and the third configuration are connected in series and the second configuration is electrically connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like is turned ON.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion on a substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, when it is referred that a “center position” of a certain configuration, for example, it may mean a position of a center of a circumscribed circle of this configuration or it may mean a center of gravity on an image of this configuration.

### First Embodiment

### [Circuit Configuration]

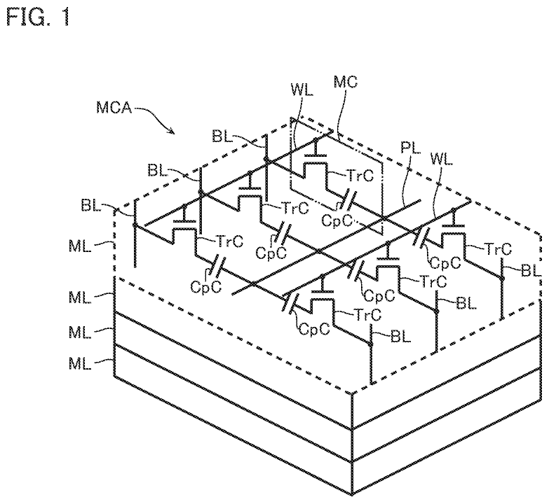

FIG. 1 is a schematic circuit diagram illustrating a configuration of a part of a semiconductor memory device according to the first embodiment. As illustrated in FIG. 1, the semiconductor memory device according to the embodiment includes a memory cell array MCA. The memory cell array MCA includes a plurality of memory layers ML, a plurality of bit lines BL connected to these plurality of memory layers ML, and a plate line PL connected to the plurality of memory layers ML.

The memory layers ML each include a plurality of word lines WL and a plurality of memory cells MC connected to these plurality of word lines WL. The memory cells MC each include a transistor TrC and a capacitor CpC. A source electrode of the transistor TrC is connected to the bit line BL. A drain electrode of the transistor TrC is connected to the capacitor CpC. A gate electrode of the transistor TrC is connected to the word line WL. One electrode of the capacitor CpC is connected to the drain electrode of the transistor TrC. The other electrode of the capacitor CpC is connected to the plate line PL. The respective bit lines BL are connected to the plurality of memory cells MC corresponding to the plurality of memory layers ML.

### [Structure]

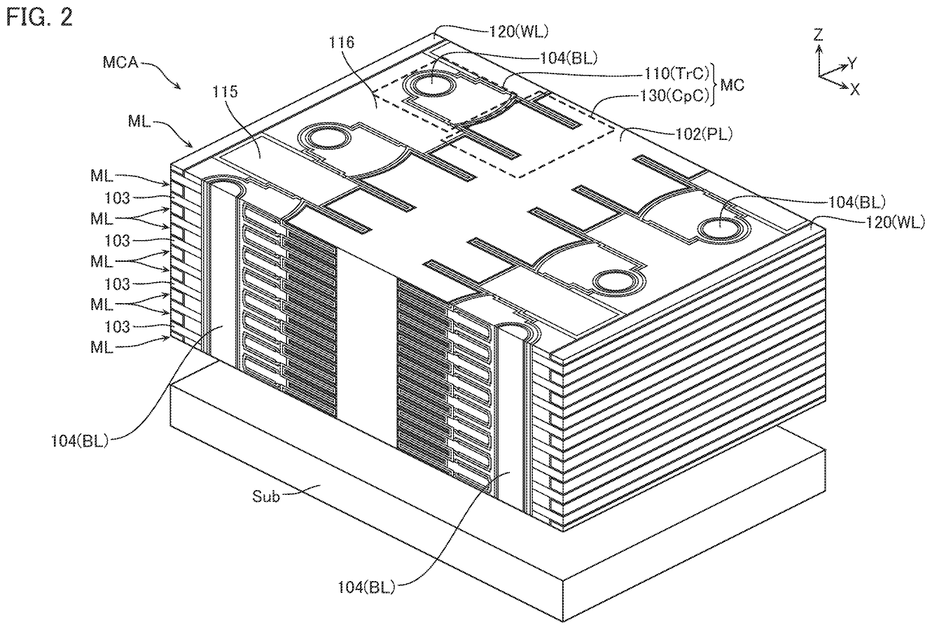

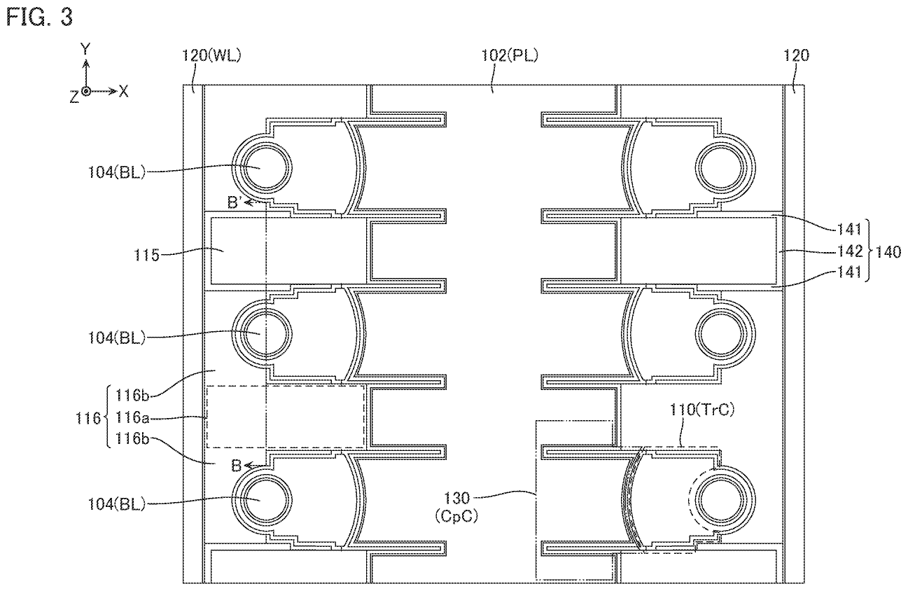

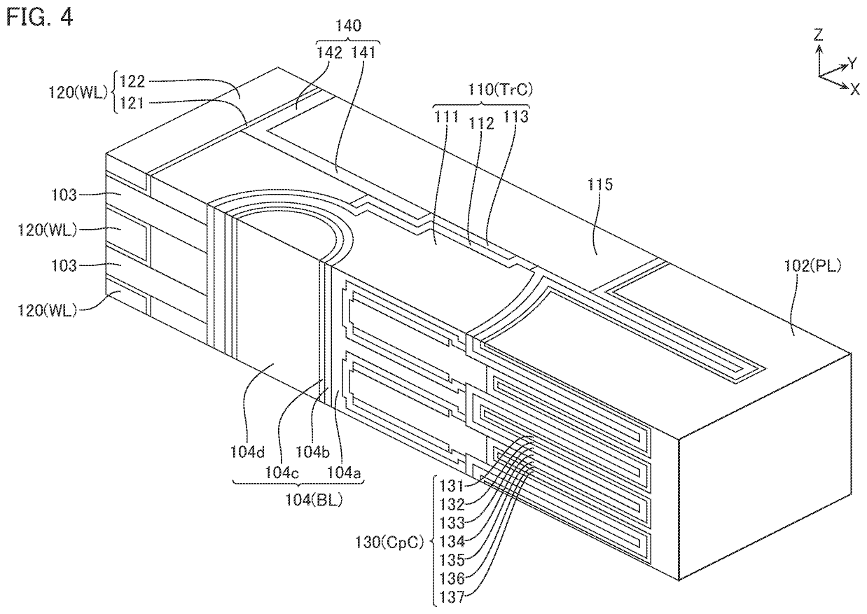

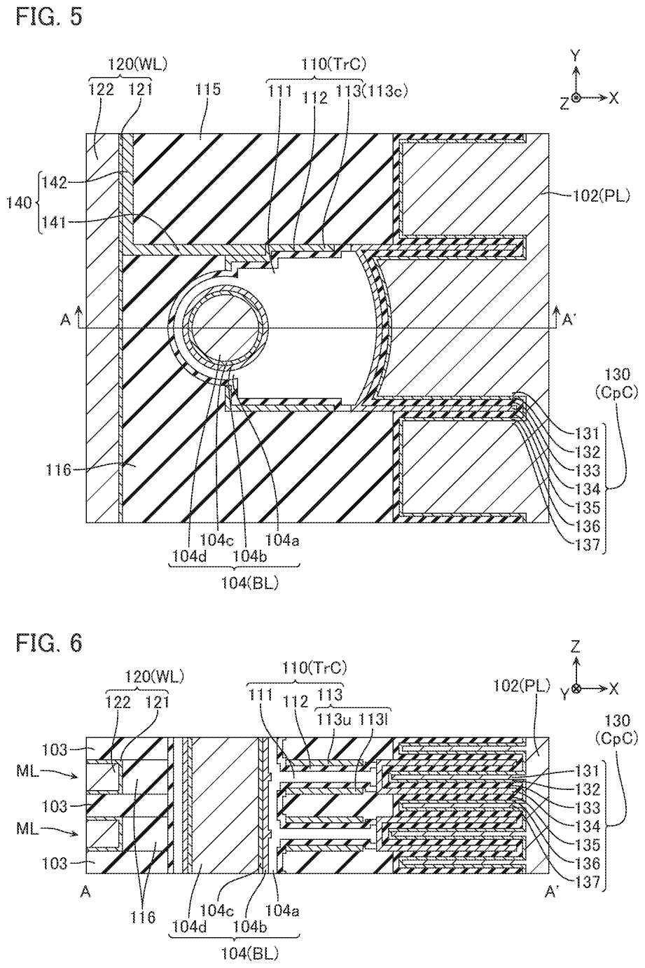

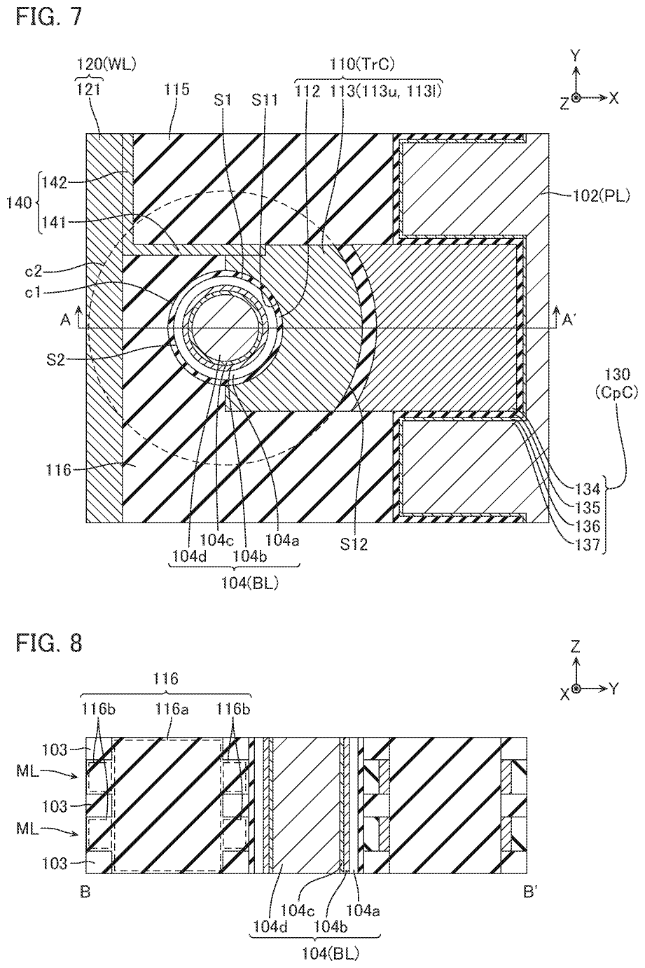

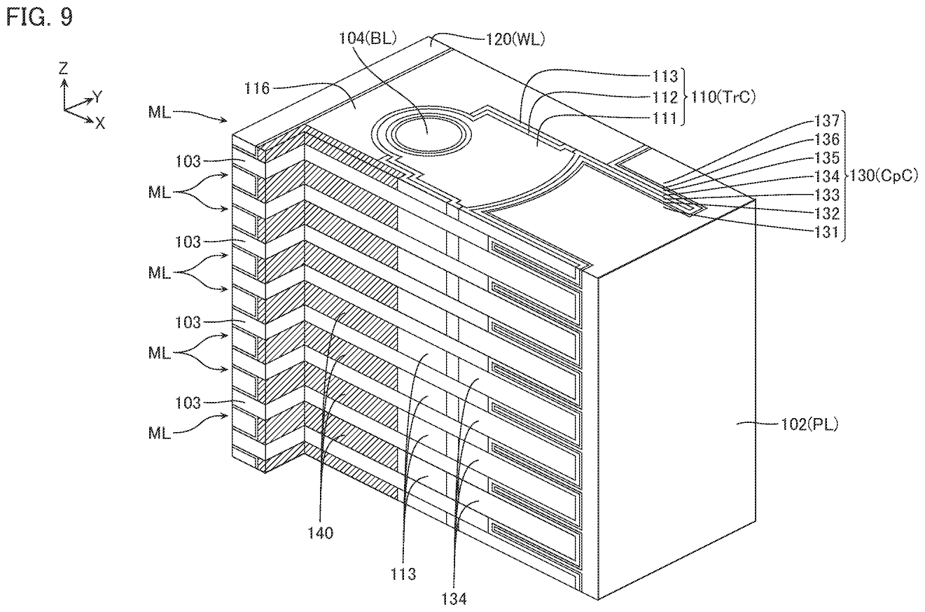

FIG. 2 is a schematic perspective view illustrating a configuration of a part of the semiconductor memory device according to the first embodiment. FIG. 3 is a schematic X-Y cross-sectional view illustrating a configuration of a part of the semiconductor memory device and illustrates a part of FIG. 2. FIG. 4 is a schematic perspective view illustrating a configuration of a part of the semiconductor memory device and illustrates an enlarged part of FIG. 2. FIG. 5 and FIG. 7 are schematic X-Y cross-sectional views illustrating configurations of parts of the semiconductor memory device. FIG. 5 illustrates an X-Y cross-sectional surface at a height position (a position in the Z-direction) corresponding to a semiconductor layer 111 described later. Additionally, FIG. 7 illustrates an X-Y cross-sectional surface at a height position (the position in the Z-direction) corresponding to a part 113u or a part 113l of a conductive layer 113 described later. FIG. 6 is a schematic cross-sectional view illustrating a configuration of a part of the semiconductor memory device and illustrates a configuration of the structure illustrated in FIG. 5 taken along the line A-A′ and viewed along the arrow direction. FIG. 8 is a schematic cross-sectional view illustrating a configuration of a part of the semiconductor memory device and illustrates a configuration of the structure illustrated in FIG. 3 taken along the line B-B′ and viewed along the arrow direction. FIG. 9 is a schematic perspective view illustrating a configuration of a part of the semiconductor memory device.

FIG. 2 illustrates a part of a semiconductor substrate Sub and the memory cell array MCA disposed above the semiconductor substrate Sub.

The semiconductor substrate Sub is, for example, a semiconductor substrate of silicon (Si) or the like containing P-type impurities, such as boron (B). An insulating layer and an electrode layer (not illustrated) are disposed on an upper surface of the semiconductor substrate Sub. The upper surface of the semiconductor substrate Sub and the insulating layer and the electrode layer (not illustrated) constitute a control circuit for controlling the semiconductor memory device according to the first embodiment. For example, in a region immediately below the memory cell array MCA, a sense amplifier circuit is disposed. The sense amplifier circuit is electrically connected to the bit lines BL. The sense amplifier circuit can read data stored in the selected memory cell MC by detecting a voltage fluctuation or a current in the bit line BL in a read operation.

The memory cell array MCA includes the plurality of memory layers ML arranged in the Z-direction. Between the respective plurality of memory layers ML, insulating layers 103, such as silicon oxide (SiO₂), are disposed.

The memory cell array MC includes a conductive layer 102. The conductive layer 102 extends in the Y-direction and the Z-direction to separate the memory layer ML in the X-direction.

The conductive layer 102 includes, for example, a stacked structure of titanium nitride (TiN) and tungsten (W). The conductive layer 102 functions as, for example, the plate line PL (FIG. 1).

The memory cell array MCA includes a plurality of via-wirings 104. The plurality of via-wirings 104 are arranged in the Y-direction, pass through the plurality of memory layers ML, and extend in the Z-direction.

For example, as illustrated in FIG. 4, the via-wiring 104 includes a semiconductor film 104a containing a material similar to the semiconductor layer 111 described later, a conductive oxide film 104b containing a conductive oxide, a barrier conductive film 104c, such as titanium nitride (TiN), and a conductive member 104d, such as tungsten (W). Note that instead of the conductive oxide film 104b, the via-wiring 104 may contain any metal including ruthenium (Ru) and iridium (Ir). The via-wiring 104 may contain only the conductive oxide or may contain only any metal including ruthenium (Ru) and iridium (Ir).

Note that, in this specification, the “conductive oxide”, for example, includes any conductive material containing oxygen including indium tin oxide (ITO), indium zinc oxide (IZO), ruthenium oxide (RuO₂), and iridium oxide (IrO₂).

The conductive member 104d has an approximately columnar shape extending in the Z-direction. The barrier conductive film 104c has an approximately cylindrical shape extending in the Z-direction along an outer peripheral surface of the conductive member 104d. The conductive oxide film 104b has an approximately cylindrical shape extending in the Z-direction along an outer peripheral surface of the barrier conductive film 104c. The semiconductor film 104a has an approximately cylindrical shape extending in the Z-direction along an outer peripheral surface of the conductive oxide film 104b. On an outer peripheral surface of the semiconductor film 104a, a part of an insulating layer 112 described later is disposed. The via-wiring 104 functions as, for example, the bit line BL (FIG. 1). The plurality of bit lines BL are, for example, as illustrated in FIG. 2, disposed corresponding to the plurality of transistors TrC included in the memory layer ML.

In an X-Y cross-sectional surface exemplified in FIG. 7, a part S1 of an outer peripheral surface of the bit line BL is opposed to the conductive layer 113 described later via a part of the insulating layer 112 described later. The other part S2 of the outer peripheral surface of the bit line BL is not opposed to the conductive layer 113.

For example, as illustrated in FIG. 3, an insulating layer 115, such as silicon oxide SiO₂, is disposed in an even-numbered or odd-numbered region counted from one side in the Y-direction among regions between the plurality of via-wirings 104 arranged in the Y-direction. An insulating layer 116, such as silicon oxide SiO₂, is disposed in other regions (the odd number or even-numbered region) among the regions of the plurality of via-wirings 104 arranged in the Y-direction. The insulating layer 115 passes through the plurality of memory layers ML and extends in the Z-direction. The insulating layer 116 includes a part 116a that passes through the plurality of memory layers ML and extends in the Z-direction and a plurality of parts 116b disposed corresponding to the plurality of memory layers ML.

### [Structure of Memory Layer ML]

As illustrated in FIG. 3, the memory layer ML includes a plurality of transistor structures 110 arranged in the Y-direction corresponding to the plurality of via-wirings 104, a conductive layer 120 disposed on a side opposite to the conductive layer 102 with respect to these plurality of transistor structures 110, and a plurality of capacitor structures 130 arranged in the Y-direction corresponding to the plurality of transistor structures 110 and disposed between the plurality of transistor structures 110 and the conductive layer 102. In each region corresponding to the insulating layer 115 among regions between the plurality of transistor structures 110 arranged in the Y-direction, a connection wiring 140 connected to the two transistor structures 110 adjacent in the Y-direction and the conductive layer 120 is disposed. In a region between the transistor structure 110 and the conductive layer 120, the part 116b of the insulating layer 116 is disposed.

For example, as illustrated in FIG. 4, the transistor structure 110 includes the semiconductor layer 111 connected to the via-wiring 104 and extending in the X-direction, the insulating layer 112 disposed on an upper surface, a lower surface, and both side surfaces in the Y-direction, and a side surface on one side in the X-direction (a conductive layer 120 side) of the semiconductor layer 111, and the conductive layer 113 disposed on an upper surface, a lower surface, and both side surfaces in the Y-direction of the insulating layer 112.

The semiconductor layer 111 function as, for example, a channel region of the transistor TrC (FIG. 1). The semiconductor layer 111 may be, for example, a semiconductor containing at least one element of gallium (Ga) and aluminum (Al), and containing indium (In), zinc (Zn), and oxygen (O), or may be another oxide semiconductor. For example, as illustrated in FIG. 6, the plurality of semiconductor layers 111 arranged in the Z-direction are connected to the via-wiring 104 extending in the Z-direction in common.

In an X-Y cross-sectional surface exemplified in FIG. 5, a center position of the semiconductor layer 111 in the Y-direction may approximately match a center position of the corresponding via-wiring 104 in the Y-direction. Additionally, a side surface of the semiconductor layer 111 on one side (a conductive layer 102 side) in the X-direction may be formed along a circle around the center position of the via-wiring 104. In the X-Y cross-sectional surface as exemplified in FIG. 5, a radius of this circle is larger than a radius of a circumscribed circle of an outer peripheral surface of the via-wiring 104 (semiconductor film 104a). Additionally, a side surface of the semiconductor layer 111 on the other side (the conductive layer 120 side) in the X-direction may be continuous with the semiconductor film 104a in the via-wiring 104. Additionally, a side surface of the semiconductor layer 111 on one side in the Y-direction (on a side opposite to the connection wiring 140) may be formed in a straight line along a side surface of the insulating layer 116 in the Y-direction. Additionally, a side surface of the semiconductor layer 111 on the other side (on a connection wiring 140 side) in the Y-direction may be formed along a step formed along side surfaces of the connection wiring 140 and the insulating layer 115 in the Y-direction.

The insulating layer 112 functions as, for example, a gate insulating film of the transistor TrC (FIG. 1). The insulating layer 112, for example, contains silicon oxide (SiO₂) or the like.

In the X-Y cross-sectional surface exemplified in FIG. 5, a side surface of the insulating layer 112 on the conductive layer 120 side in the X-direction may cover a part of the outer peripheral surface of the via-wiring 104 (a part disposed on the conductive layer 120 side in the outer peripheral surface of the via-wiring 104) and may be formed along the circle around the center position of the via-wiring 104. A side surface of the insulating layer 112 on one side (on a side opposite to the connection wiring 140) in the Y-direction may be formed in a straight line along the side surface of the insulating layer 116 in the Y-direction. A side surface of the insulating layer 112 on the other side (on the connection wiring 140 side) in the Y-direction may be formed along the step formed along the side surfaces of the connection wiring 140 and the insulating layer 115 in the Y-direction.

In the X-Y cross-sectional surface as exemplified in FIG. 7, the insulating layer 112 may cover the outer peripheral surface of the via-wiring 104 over a whole circumference.

The conductive layer 113 functions as, for example, the gate electrode of the transistor TrC (FIG. 1). The conductive layer 113, for example, contains a conductive oxide, such as titanium nitride (TiN) and indium tin oxide (ITO). For example, as illustrated in FIG. 3, the plurality of conductive layers 113 arranged in the Y-direction are connected to the conductive layer 120 extending in the Y-direction in common via the connection wiring 140. The conductive layer 113 is opposed to an upper surface, a lower surface, both side surfaces in the Y-direction, and a side surface on one side (the conductive layer 120 side) in the X-direction of the semiconductor layer 111 via the insulating layer 112.

In the X-Y cross-sectional surface exemplified in FIG. 5, a center position of the conductive layer 113 in the Y-direction may approximately match the center position of the corresponding via-wiring 104 in the Y-direction. Additionally, a side surface of the conductive layer 113 on one side (on a side opposite to the connection wiring 140) in the Y-direction may be formed in the straight line along the side surface of the insulating layer 116 in the Y-direction. Additionally, a side surface of the conductive layer 113 on the other side (on the connection wiring 140 side) in the Y-direction may be formed along a step formed along side surfaces of the connection wiring 140 and the insulating layer 115 in the Y-direction.

In the X-Y cross-sectional surface exemplified in FIG. 7, the center position of the conductive layer 113 in the Y-direction may approximately match the center position of the corresponding via-wiring 104 in the Y-direction. Additionally, a side surface S12 of the conductive layer 113 on one side (on the conductive layer 102 side) in the X-direction may be formed along a circle c2 around the center position of the via-wiring 104. As illustrated in FIG. 7, a side surface of the conductive layer 113 on the other side (the conductive layer 120 side) in the X-direction may include two linear parts that are spaced in the Y-direction and extend in the Y-direction and a curved part S11 disposed between these two linear parts. This curved part S11 may be formed along a circle c1 around the center position of the via-wiring 104 (in the illustrated example, the circle c1 corresponds to an outer peripheral surface of the insulating layer 112. A radius of the circle c2 is larger than a radius of the circle c1.) and may be opposed to the part S1 of the outer peripheral surface of the via-wiring 104 via the insulating layer 112. A side surface of the conductive layer 113 on one side (on a side opposite to the connection wiring 140) in the Y-direction may be formed in a straight line along the side surface of the insulating layer 116 in the Y-direction. Additionally, the side surface of the conductive layer 113 on the other side (on the connection wiring 140 side) in the Y-direction may be formed along the step formed along the side surfaces of the connection wiring 140 and the insulating layer 115 in the Y-direction.

Note that FIG. 6 notates a part of the conductive layer 113 covering an upper surface of the semiconductor layer 111 as the part 113u and a part of the conductive layer 113 covering a lower surface of the semiconductor layer 111 as the part 113l. FIG. 5 denotes a part 113c of the conductive layer 113 disposed between the part 113u and the part 113l. The part 113c, which extends in the Z-direction, has an upper end continuous with the part 113u, and has a lower end continuous with the part 113l. The part 113c is in contact with a side surface of the connection wiring 140 in the Y-direction.

The conductive layer 120 functions as, for example, the word line WL (FIG. 1). For example, as illustrated in FIG. 3, the conductive layer 120 extends in the Y-direction and is connected to the plurality of conductive layers 113 arranged in the Y-direction via the connection wiring 140. As illustrated in FIG. 4, the conductive layer 120, for example, includes a barrier conductive film 121, such as titanium nitride (TiN), and a conductive film 122 of tungsten (W).

As illustrated in FIG. 7, a distance between the conductive layer 120 and the via-wiring 104 is larger than a distance between the conductive layer 113 and the via-wiring 104 (a thickness of the insulating layer 112).

For example, as illustrated in FIG. 5 and FIG. 6, the capacitor structure 130 includes a conductive layer 131, a conductive layer 132 disposed on an upper surface, a lower surface, both side surfaces in the Y-direction, and a side surface on one side in the X-direction (a transistor structure 110 side) of the conductive layer 131, an insulating layer 133 disposed on an upper surface, a lower surface, both side surfaces in the Y-direction, and a side surface on one side in the X-direction (the transistor structure 110 side) of the conductive layer 132, a conductive layer 134 disposed on an upper surface, a lower surface, both side surfaces in the Y-direction, and a side surface on one side in the X-direction (the transistor structure 110 side) of the insulating layer 133, an insulating layer 135 disposed on an upper surface, a lower surface, and both side surfaces in the Y-direction of the conductive layer 134, a conductive layer 136 disposed on an upper surface, a lower surface, and both side surfaces in the Y-direction of the insulating layer 135, and a conductive layer 137 disposed on an upper surface, a lower surface, and both side surfaces in the Y-direction of the conductive layer 136.

The conductive layers 131, 132, 136, 137 function as one electrodes of the capacitors CpC (FIG. 1). The conductive layers 131, 137, for example, contain tungsten (W) or the like. The conductive layers 132, 136, for example, contain titanium nitride (TiN) or the like. The conductive layers 131, 132, 136, 137 are connected to the conductive layer 102.

The insulating layers 133, 135 function as insulating layers of the capacitors CpC (FIG. 1). The insulating layers 133, 135, for example, may be zirconia (ZrO₂), alumina (Al₂O₃), or another insulating metal oxide. The insulating layers 133, 135, for example, may be a stacked film of a plurality of insulating metal oxides (for example, a stacked film of zirconia and alumina).

The conductive layer 134 functions as, for example, the other electrode of the capacitor CpC (FIG. 1). The conductive layer 134, for example, contains a conductive oxide of indium tin oxide (ITO) or the like. The conductive layer 134 is insulated from the conductive layers 131, 132, 136, 137 via the insulating layers 133, 135. The conductive layer 134 is connected to a side surface of the semiconductor layer 111 in the X-direction.

For example, as illustrated in FIG. 3, the connection wiring 140 includes two parts 141 extending in the X-direction and a part 142 continuous with end portions on the conductive layer 120 side of these two parts 141 and extends in the Y-direction. The end portion of the part 141 on the conductive layer 102 side extends in the X-direction along a side surface of the conductive layer 113 in the Y-direction and is in contact with this side surface. The part 142 extends along a side surface of the conductive layer 120 on the transistor structure 110 side in the Y-direction and is in contact with this side surface.

In the example of FIG. 9, a length of the connection wiring 140 in the Z-direction matches a length of the conductive layer 113 in the Z-direction, a length of the conductive layer 120 in the Z-direction, and a length of the conductive layer 134 in the Z-direction. In the example of FIG. 9, the connection wiring 140 is in contact with the two insulating layers 103 adjacent in the Z-direction.

### [Manufacturing Method]

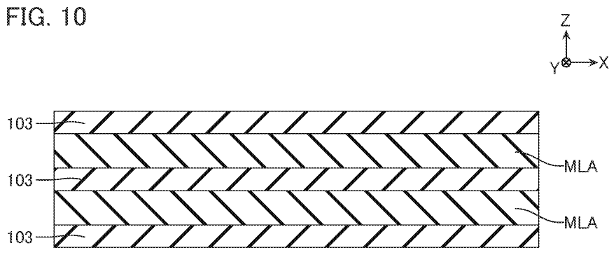

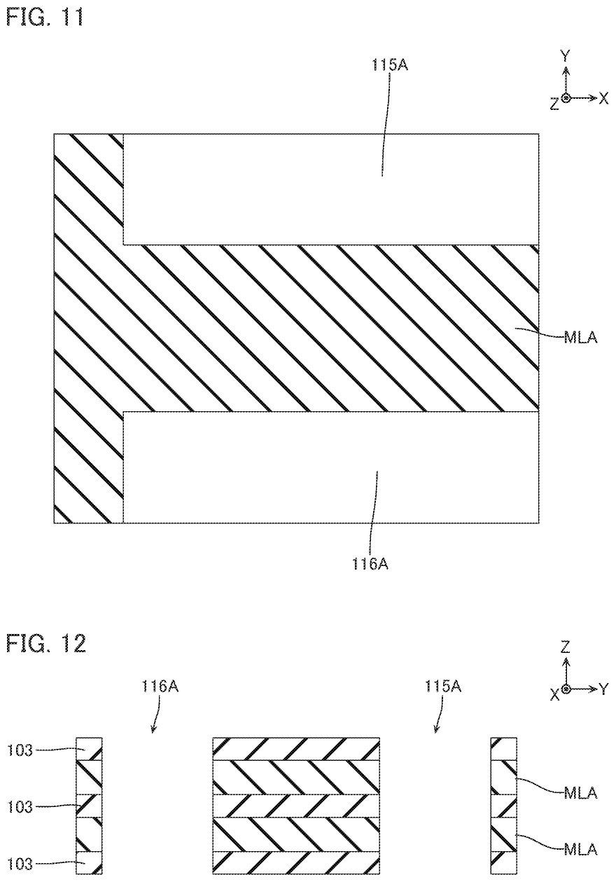

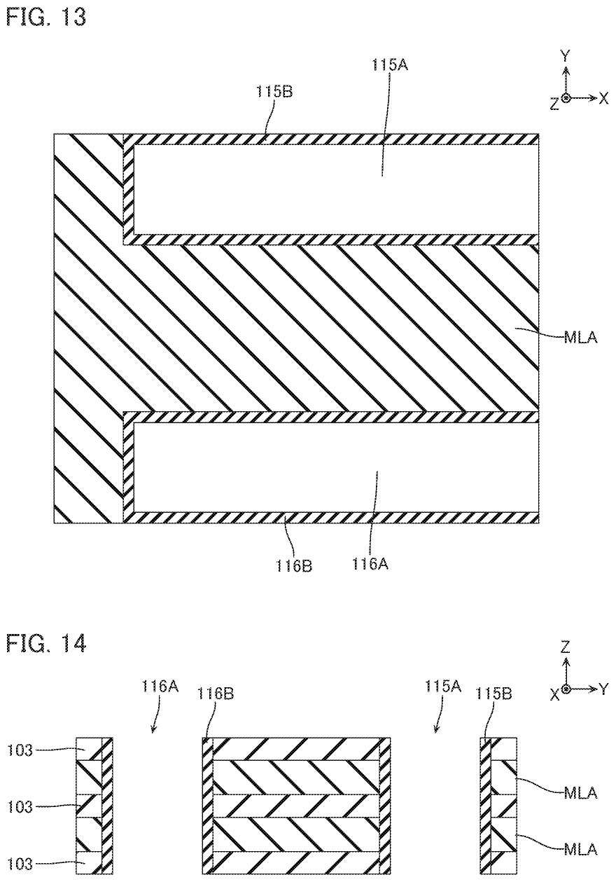

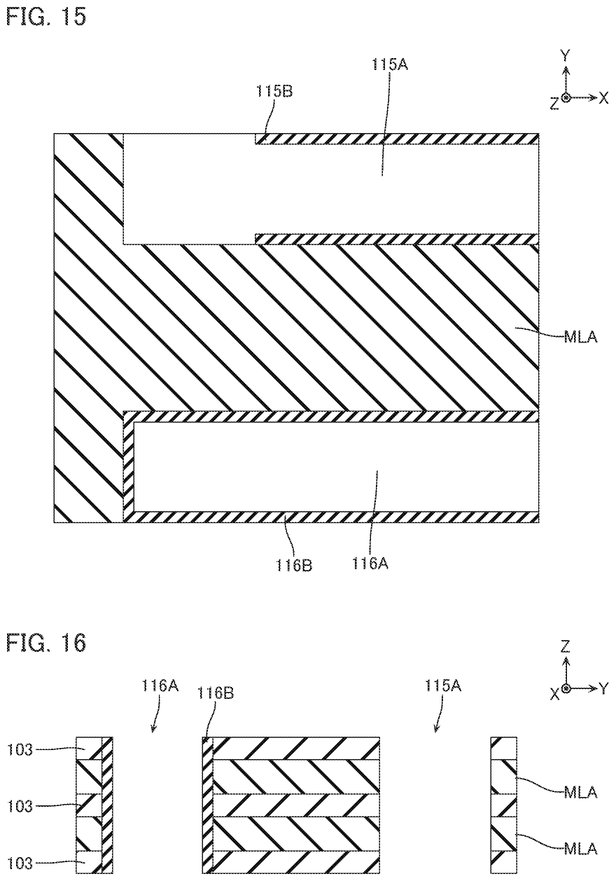

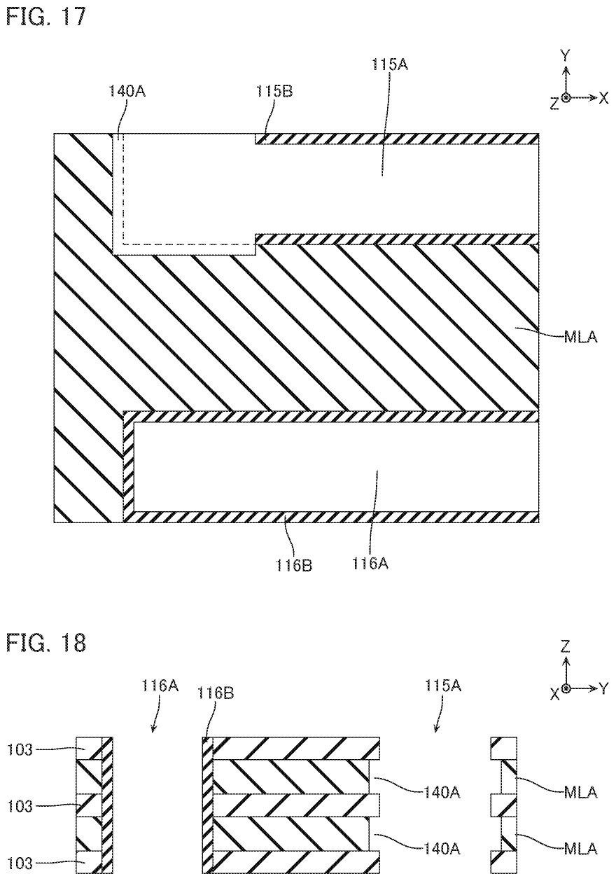

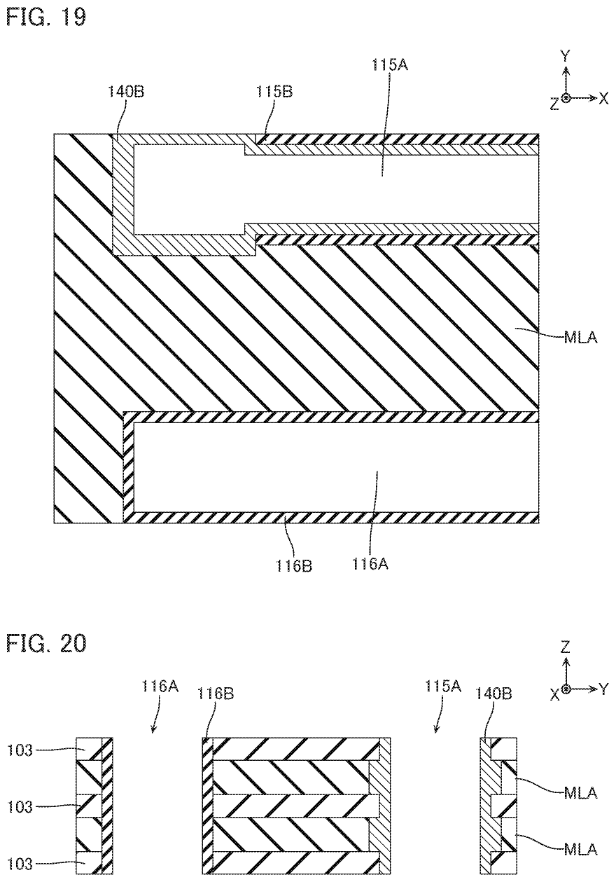

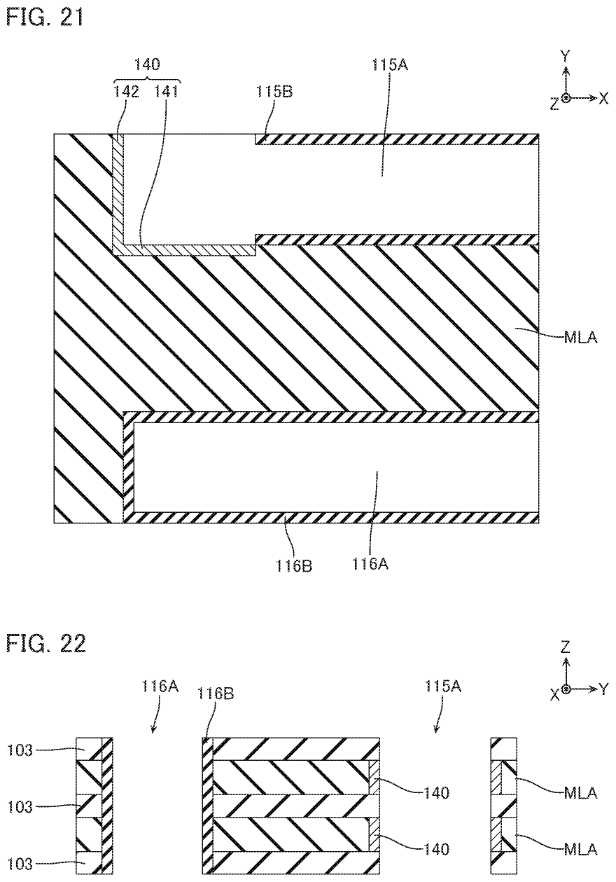

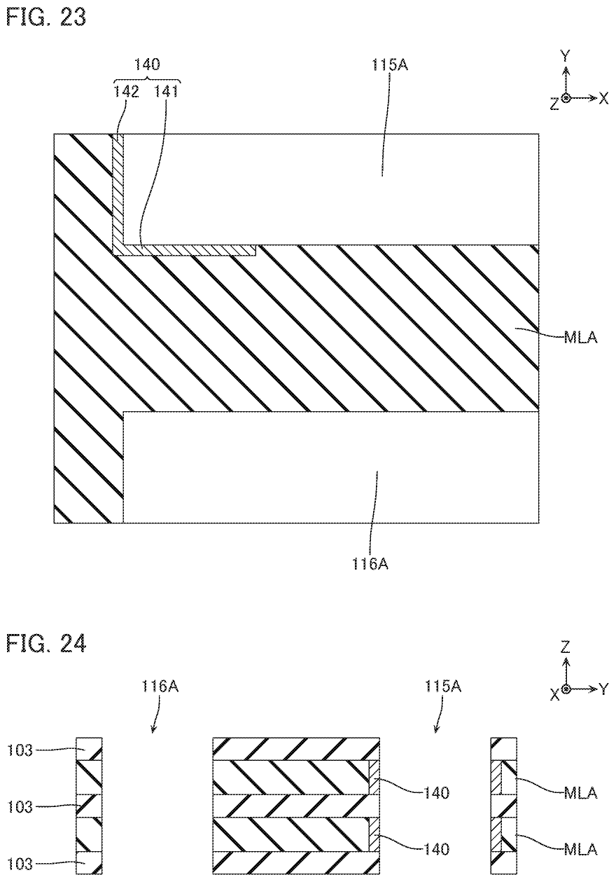

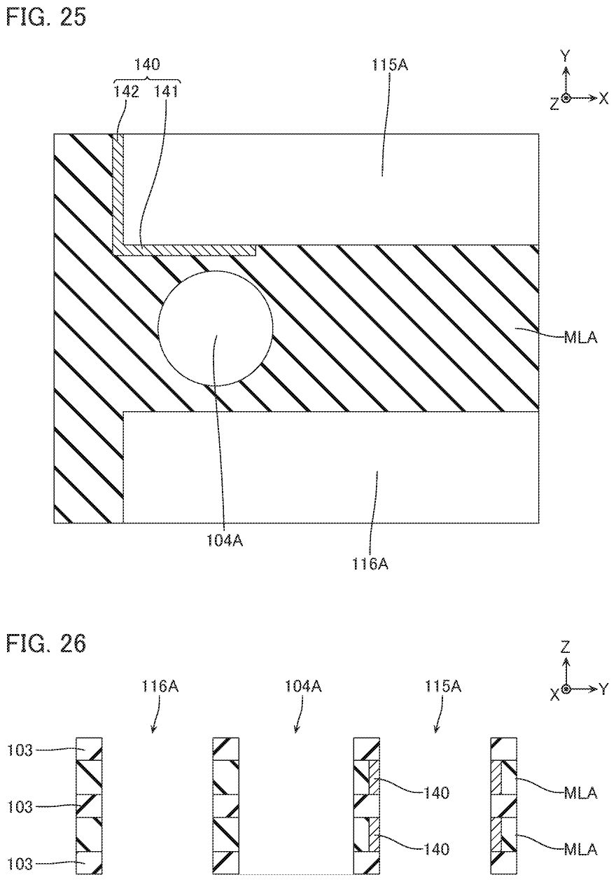

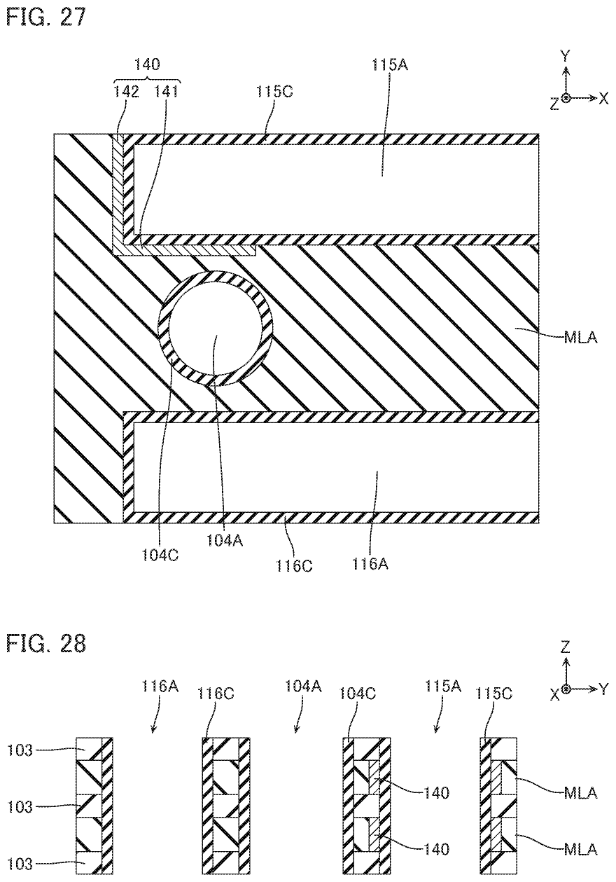

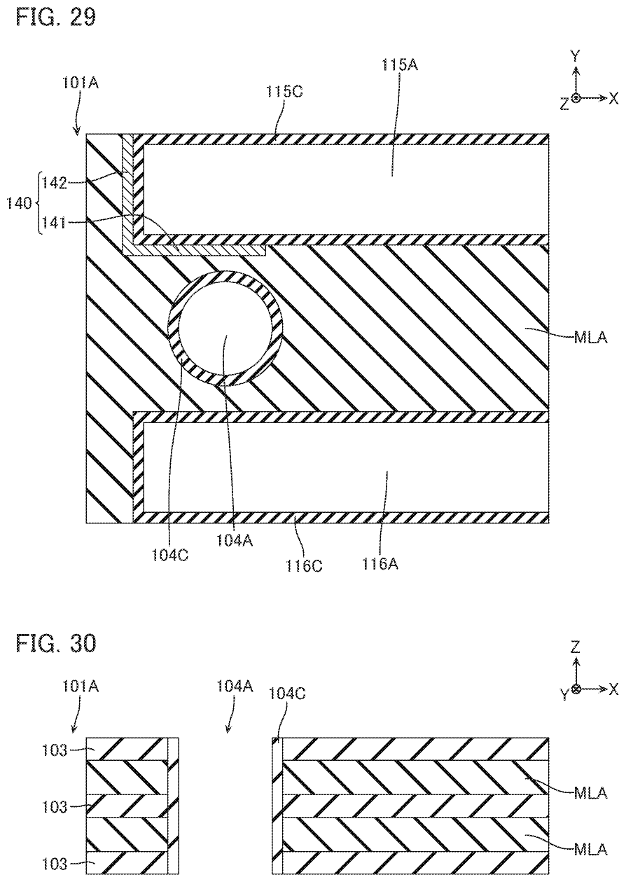

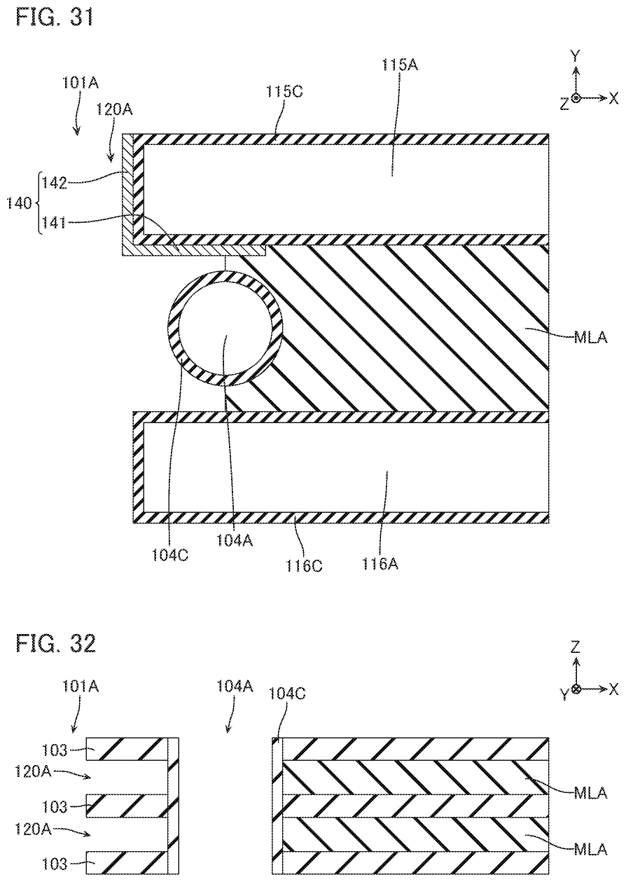

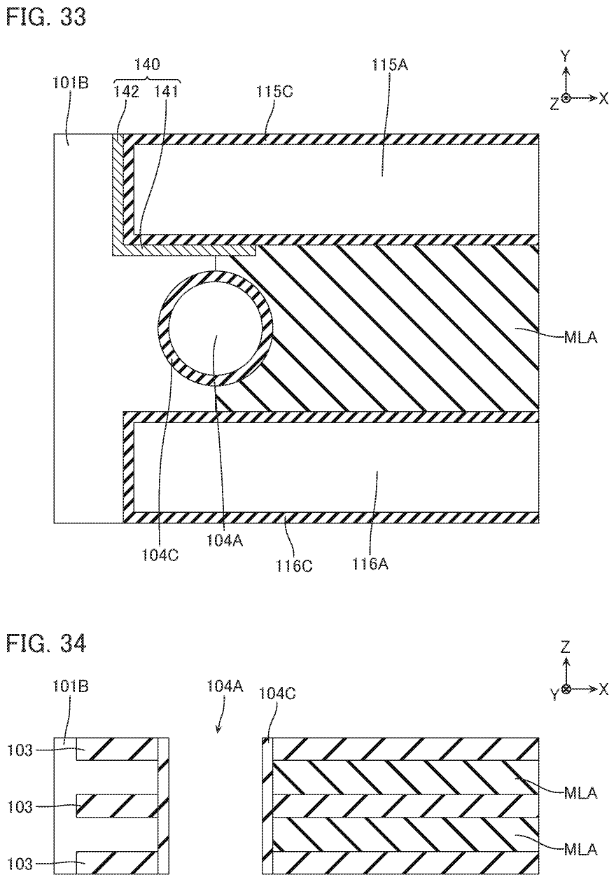

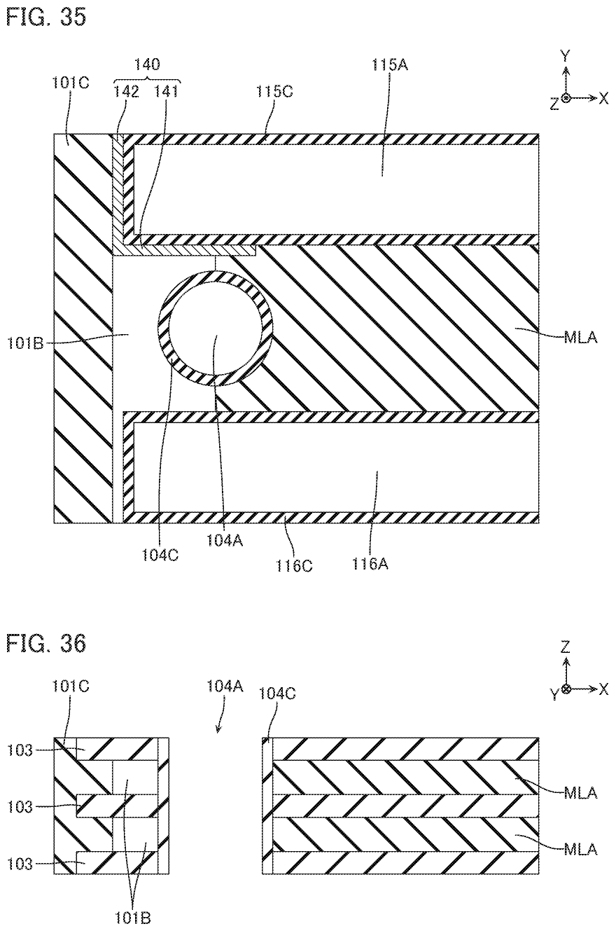

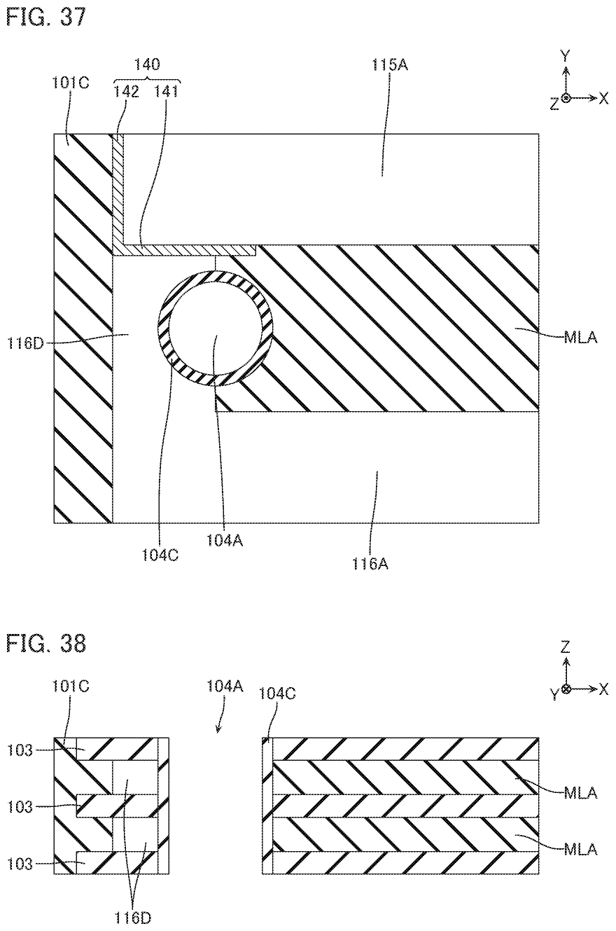

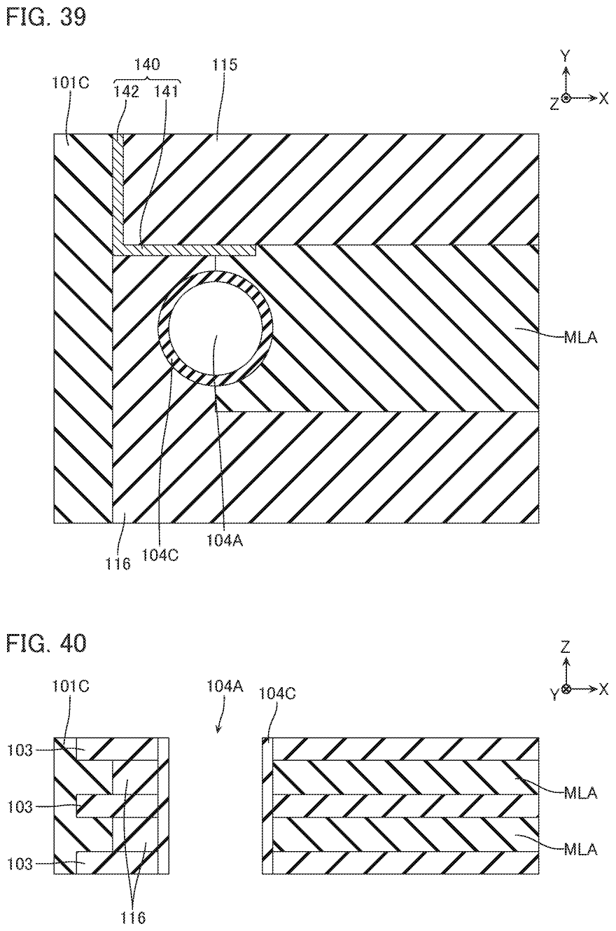

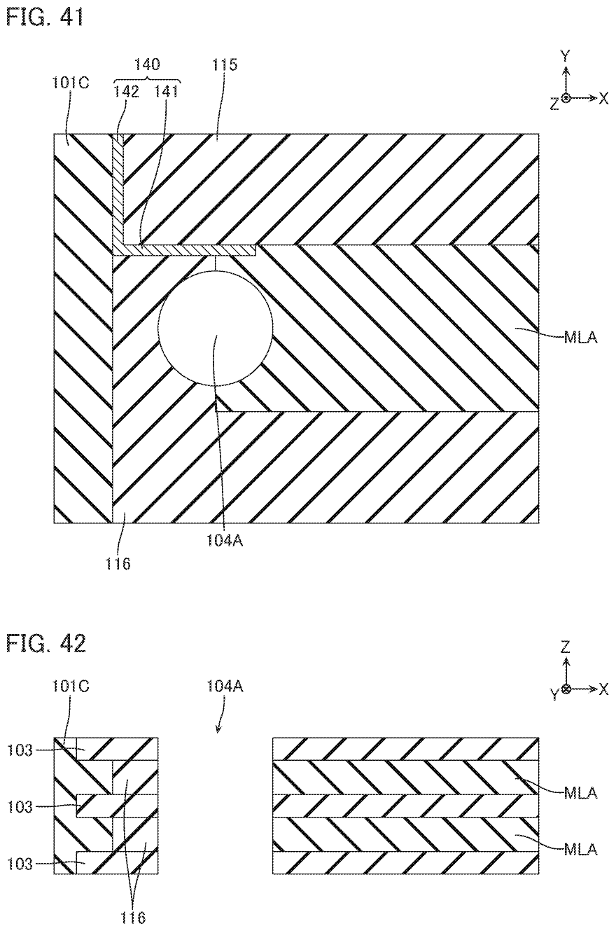

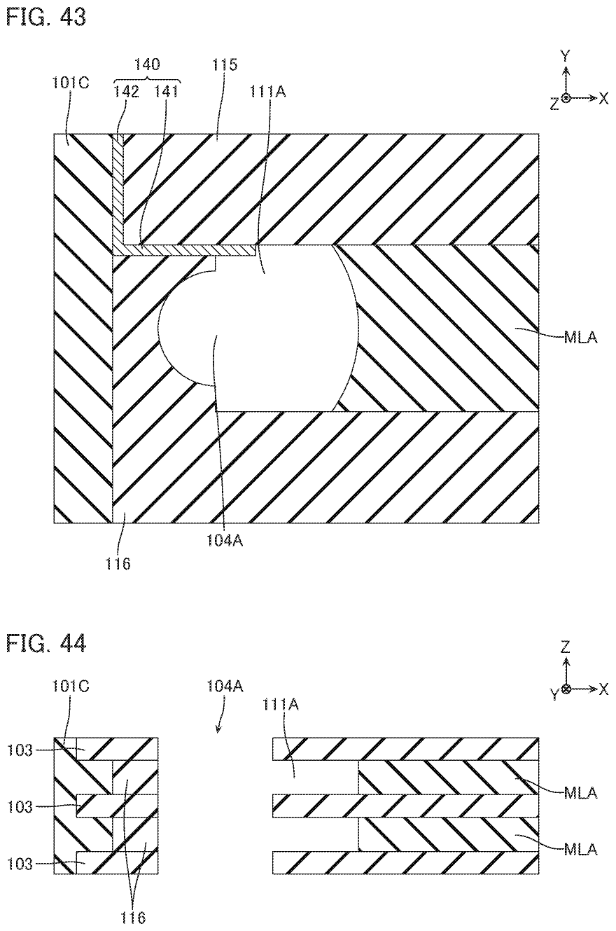

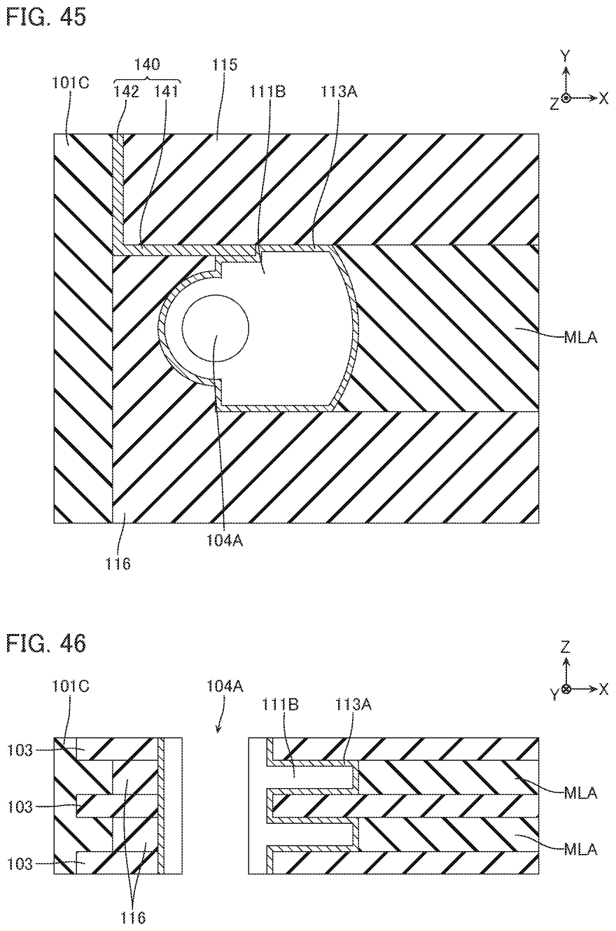

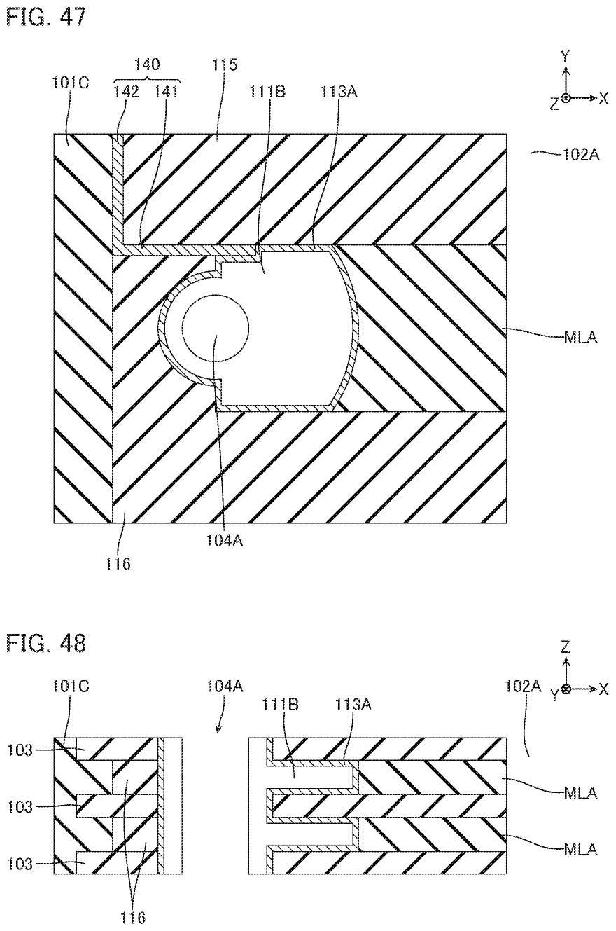

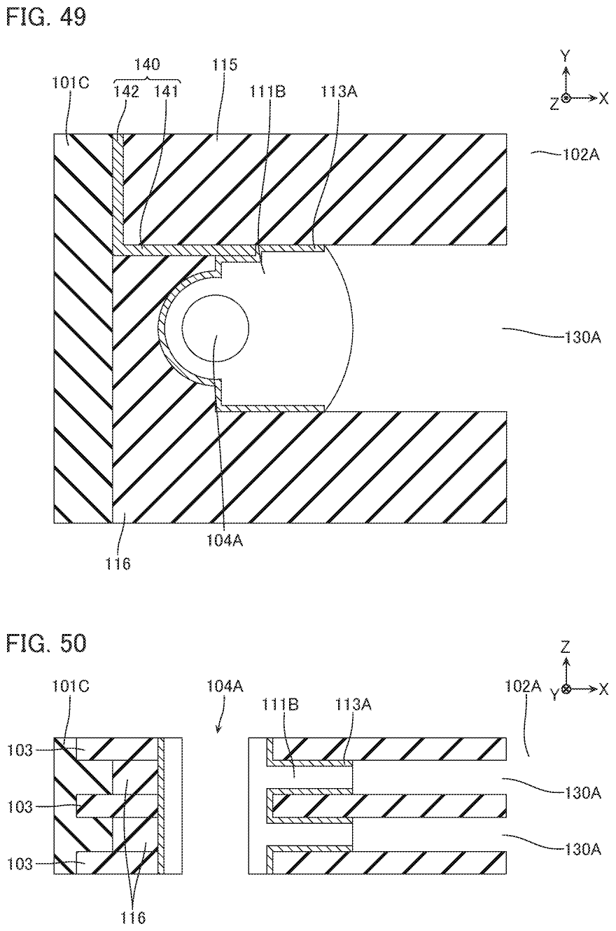

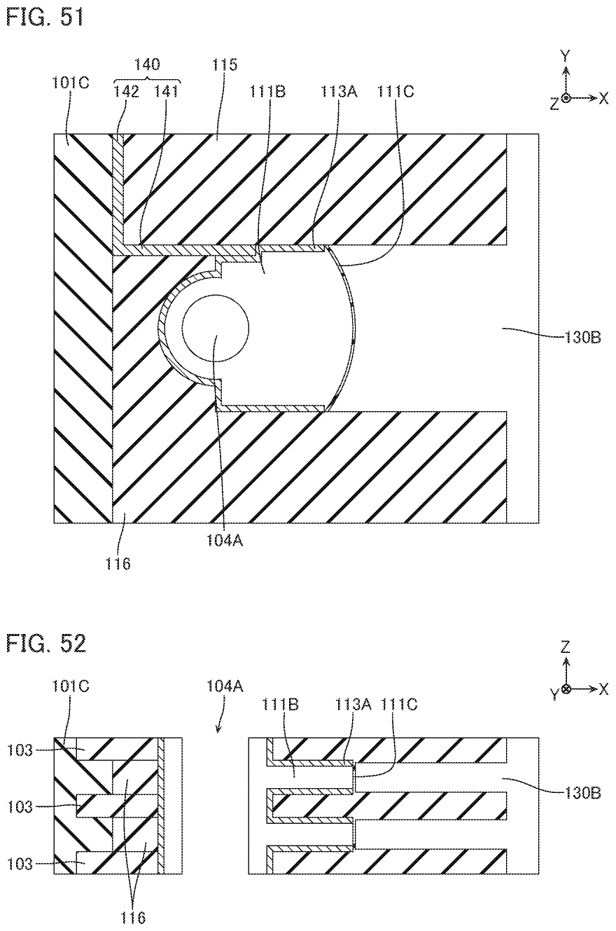

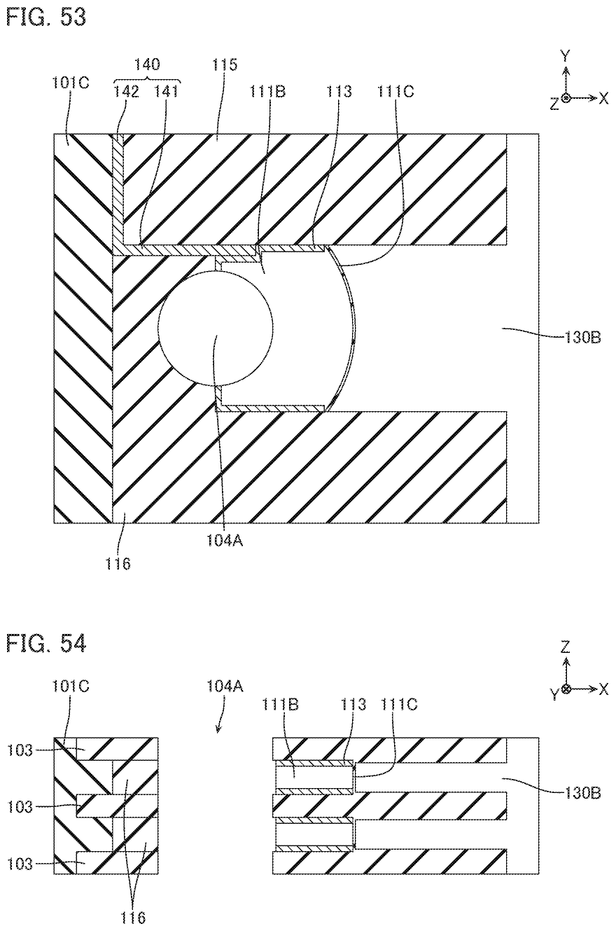

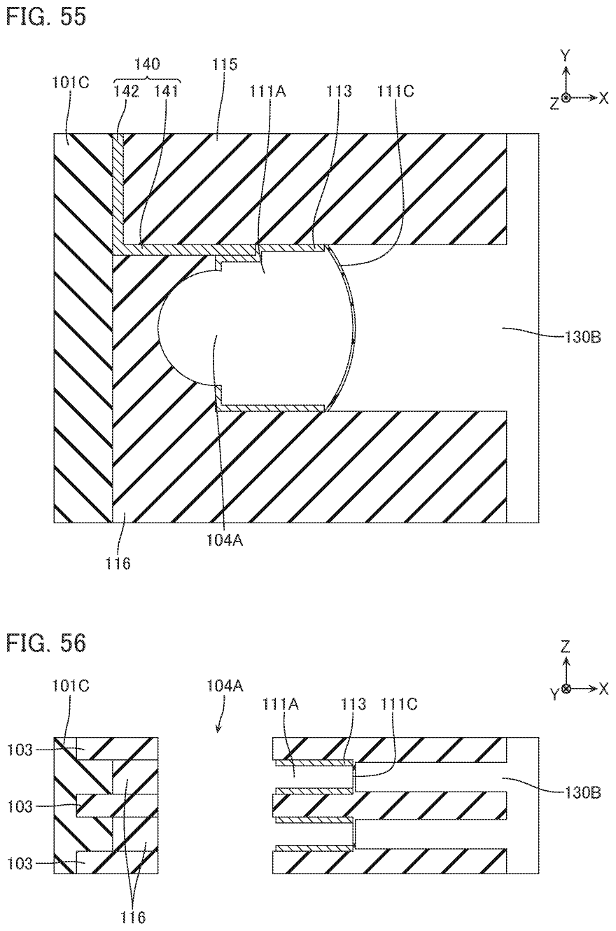

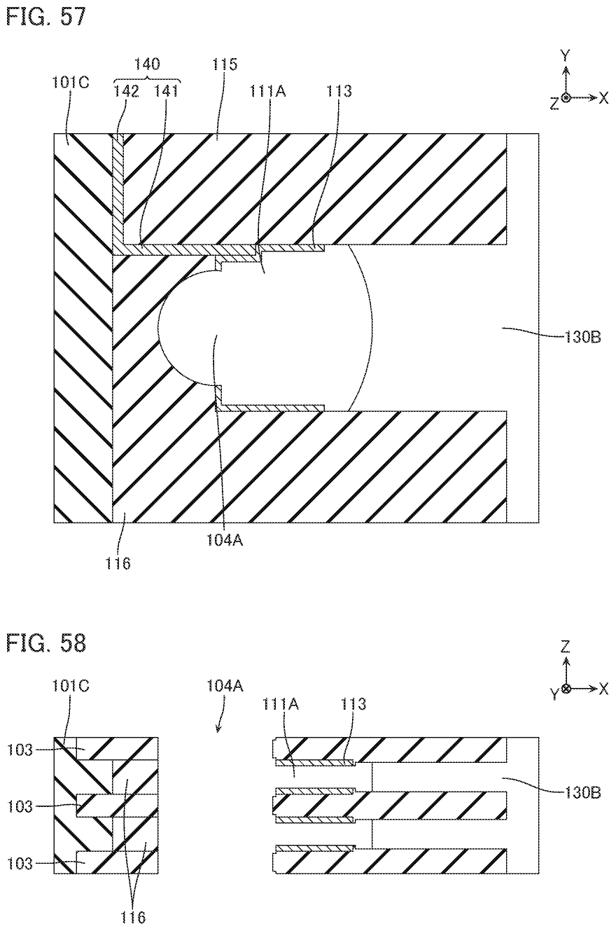

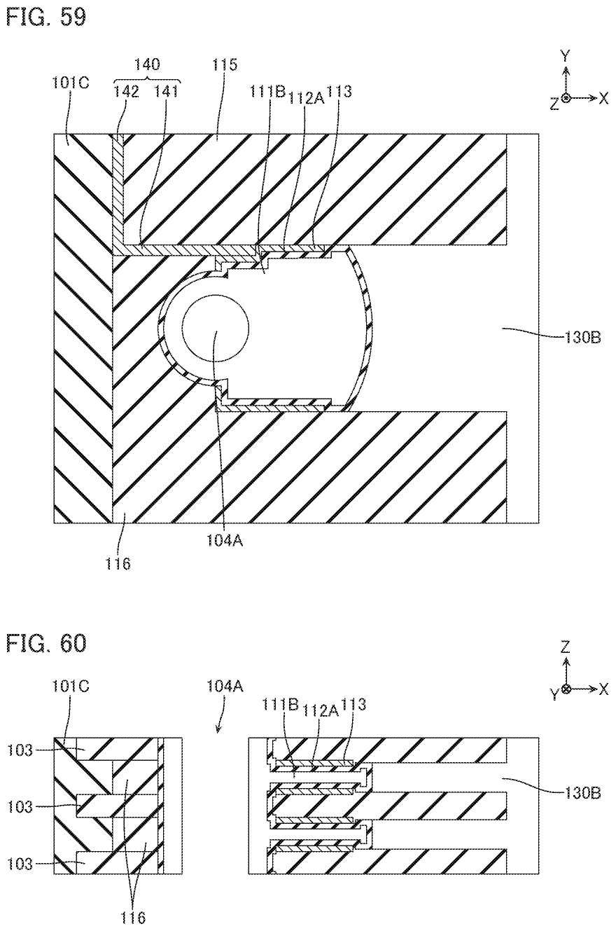

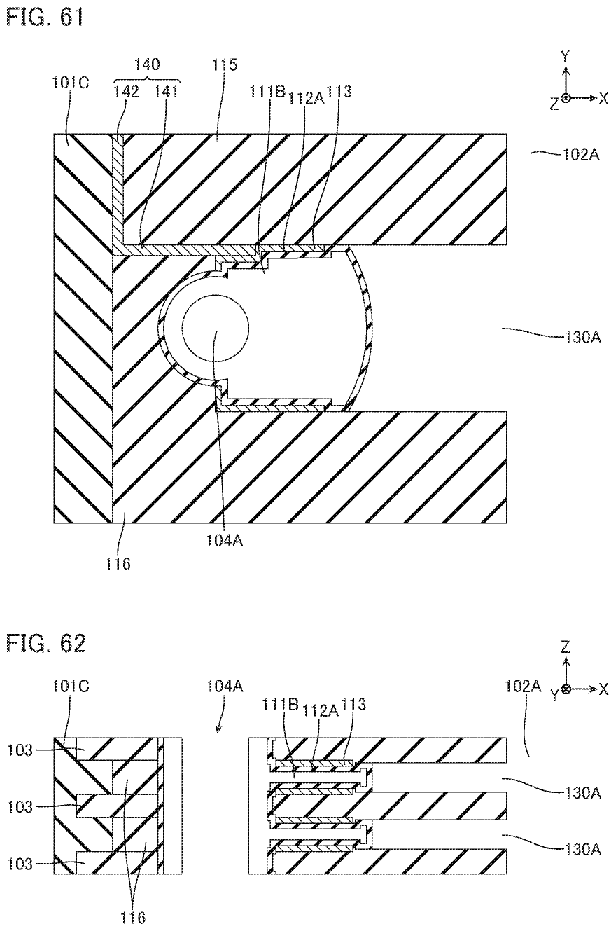

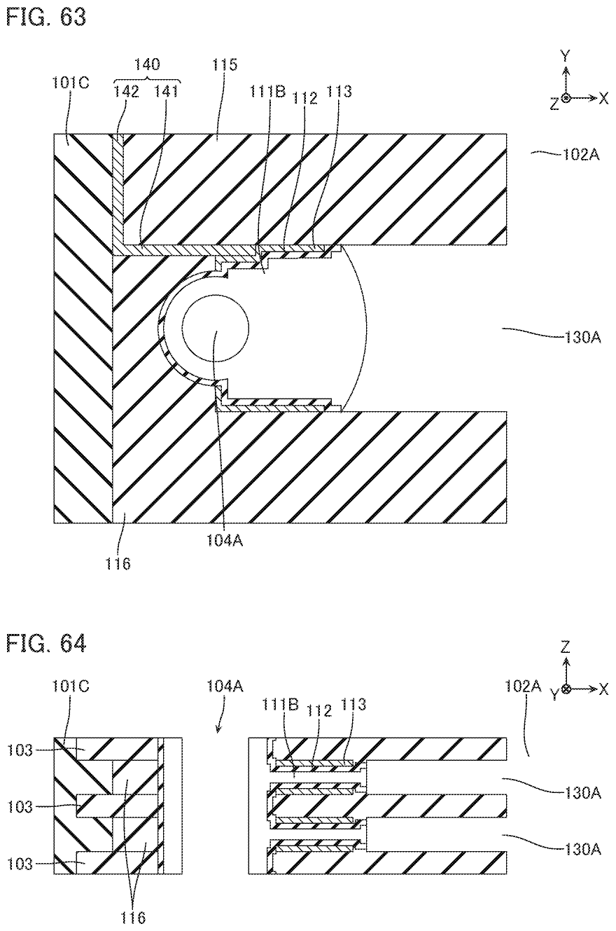

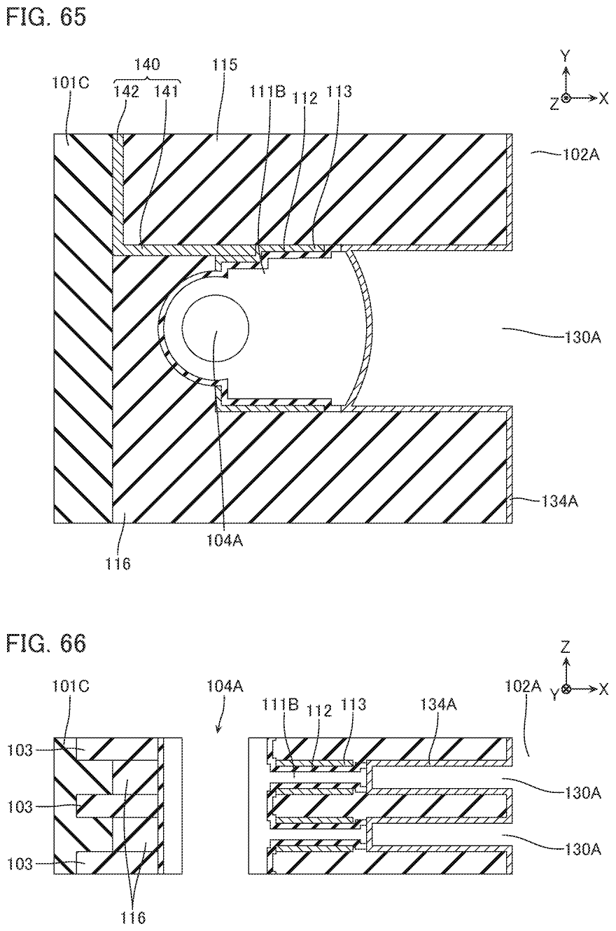

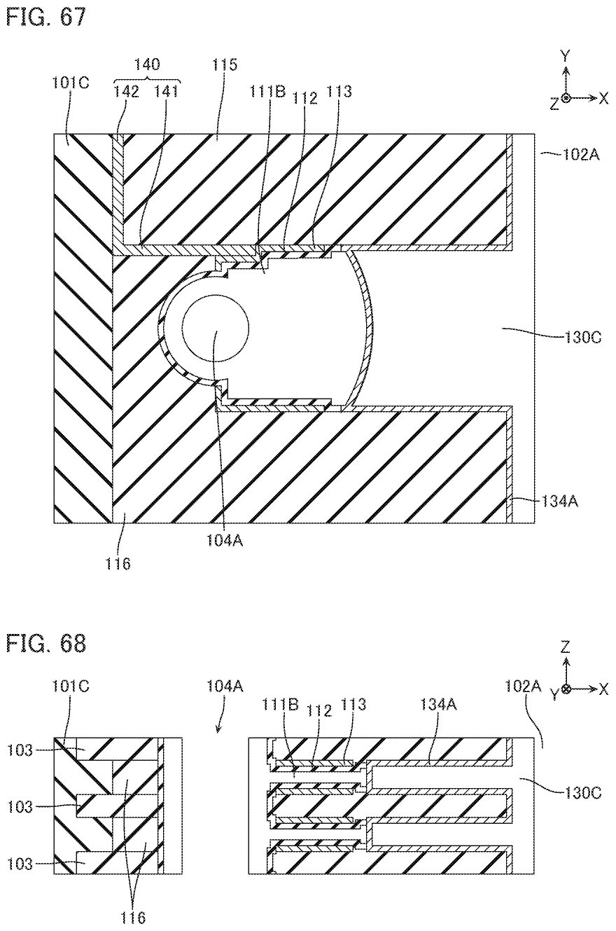

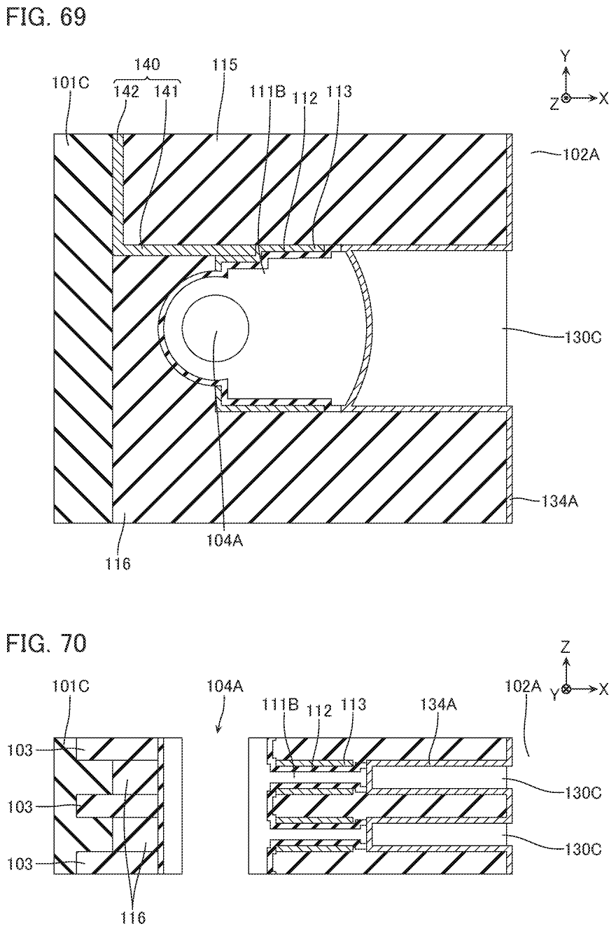

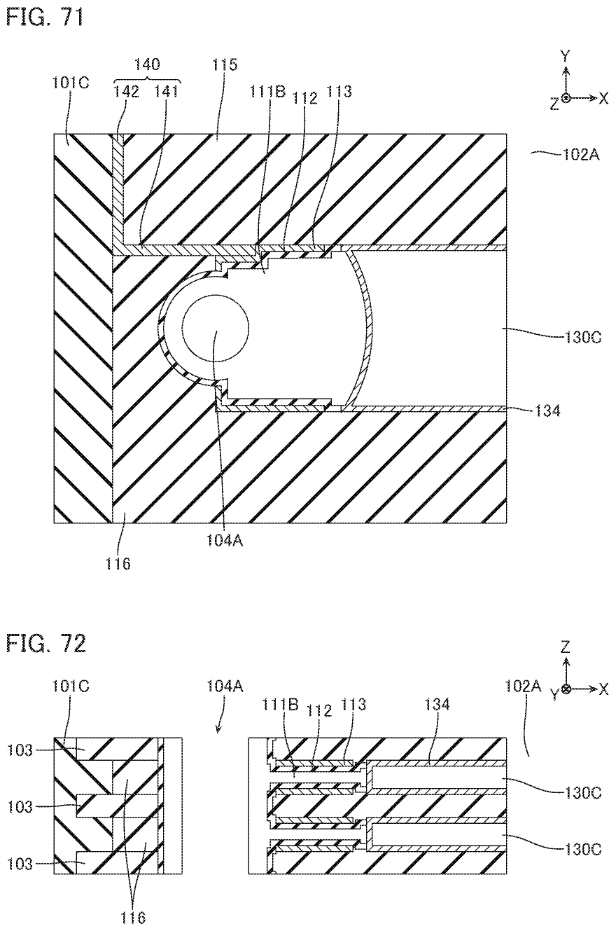

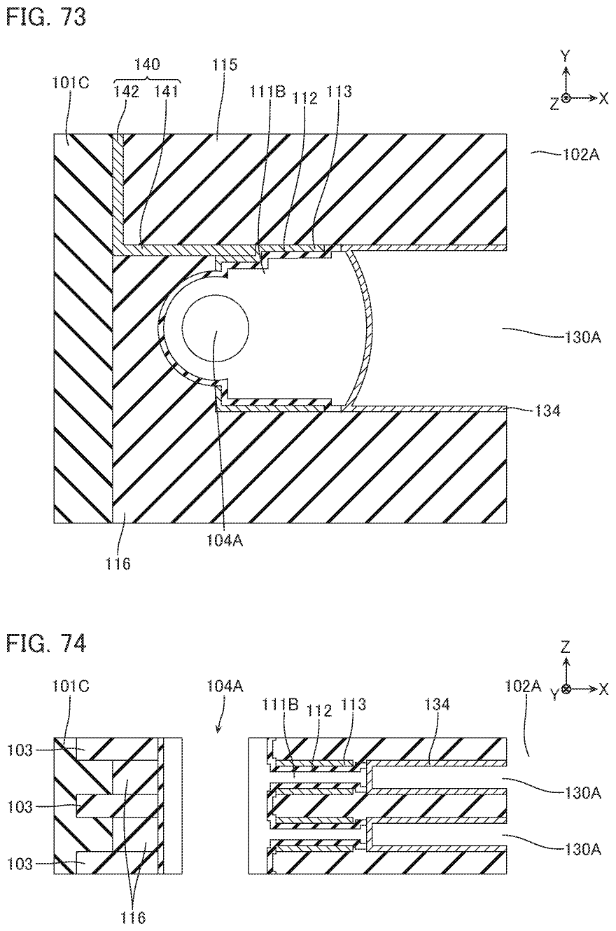

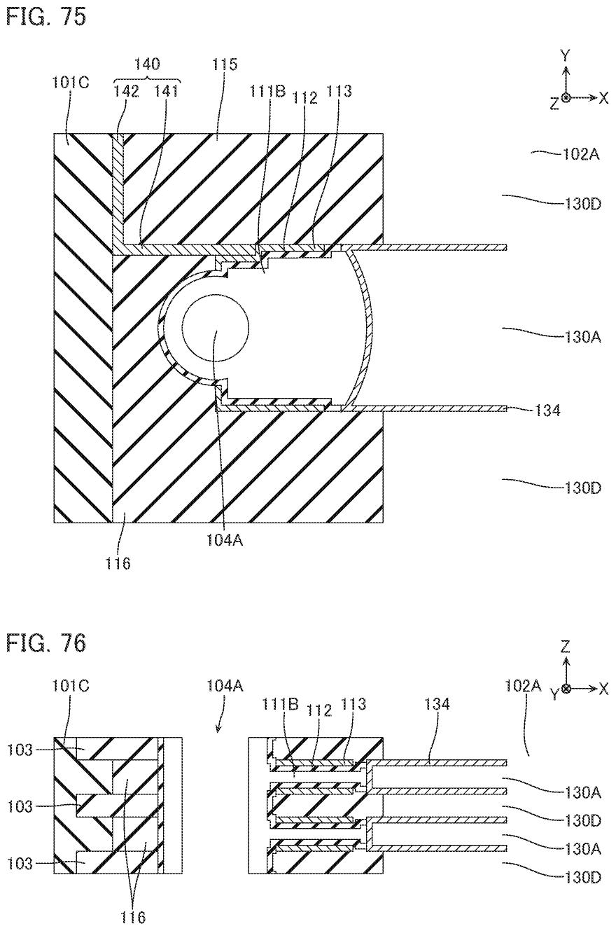

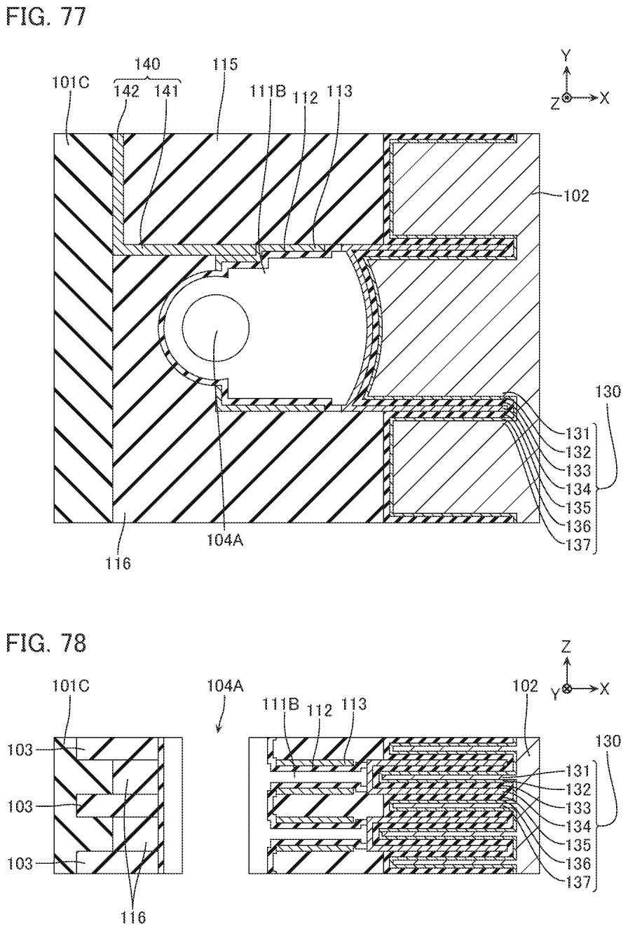

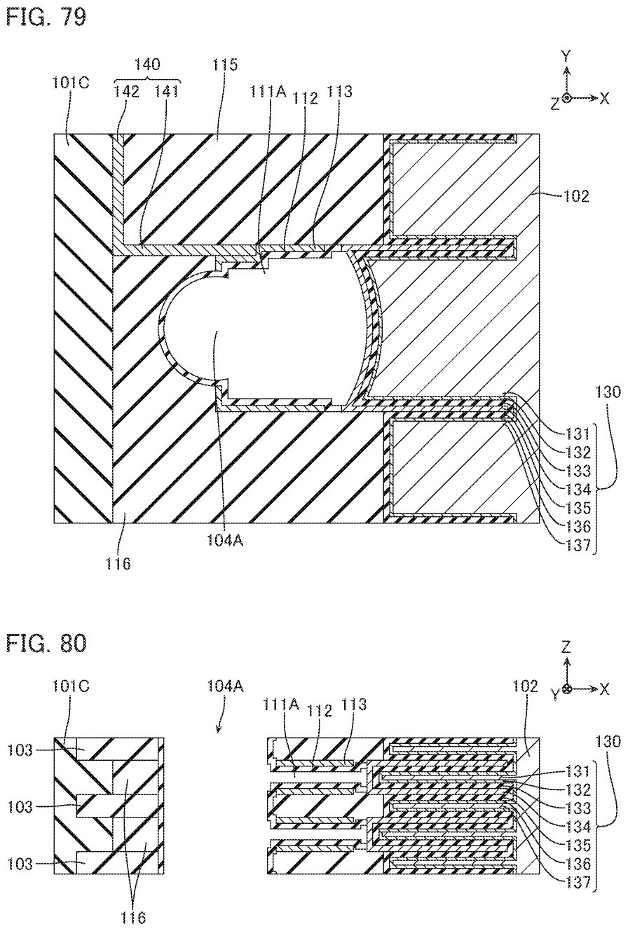

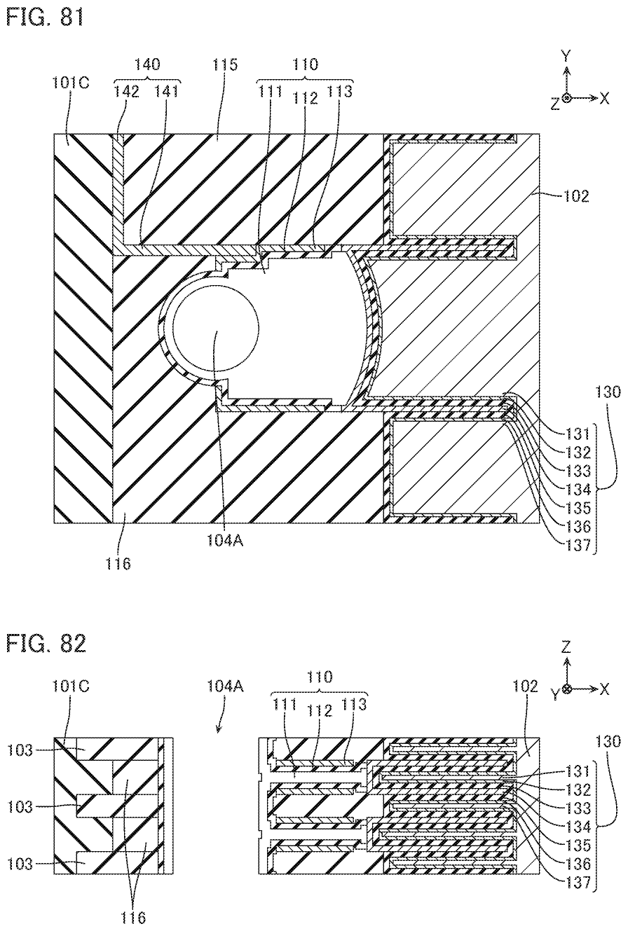

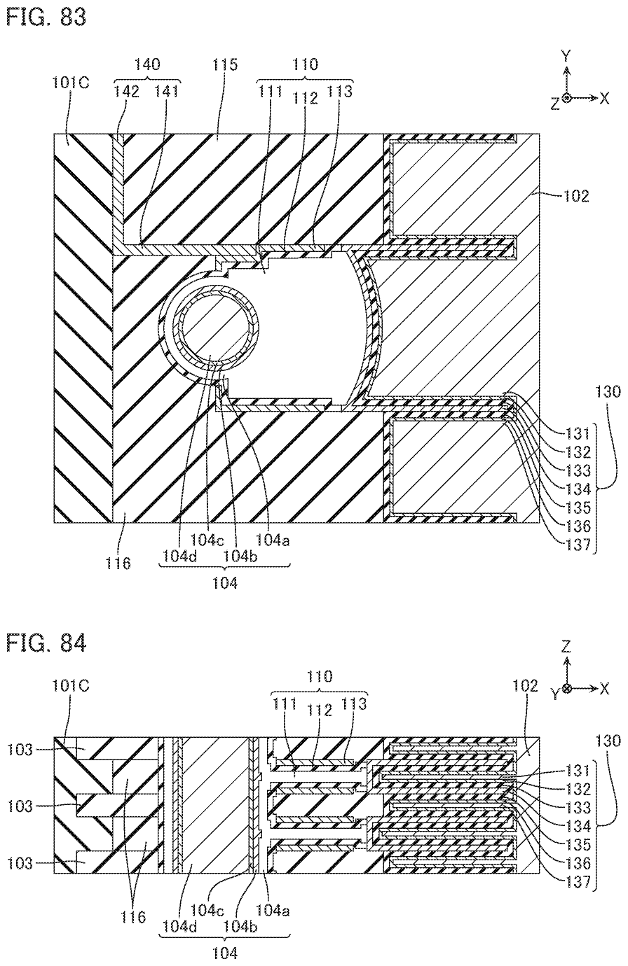

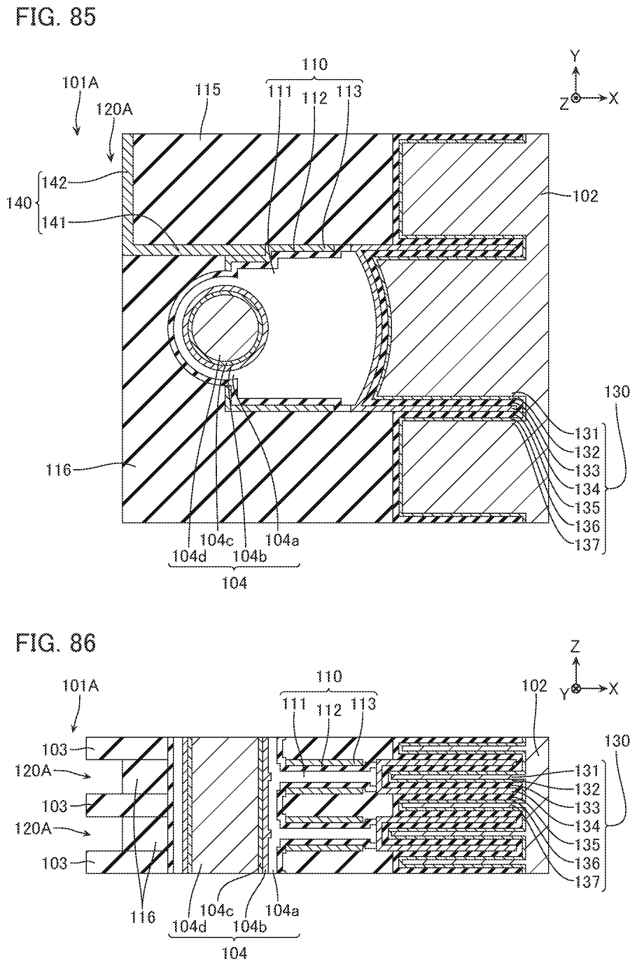

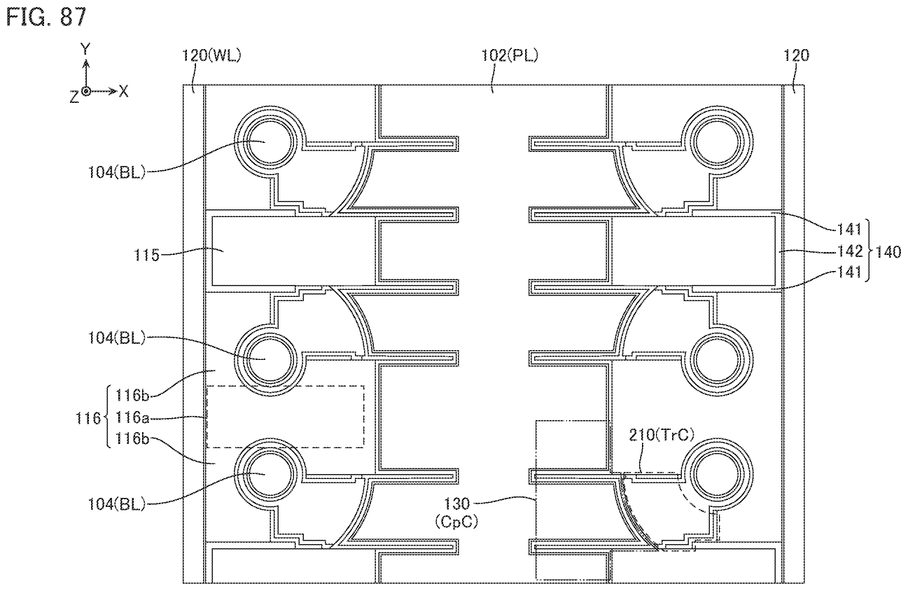

FIG. 10 to FIG. 86 are schematic cross-sectional views for describing the manufacturing method of the semiconductor memory device according to the first embodiment. FIG. 10, FIG. 30, FIG. 32, FIG. 34, FIG. 36, FIG. 38, FIG. 40, FIG. 42, FIG. 44, FIG. 46, FIG. 48, FIG. 50, FIG. 52, FIG. 54, FIG. 56, FIG. 58, FIG. 60, FIG. 62, FIG. 64, FIG. 66, FIG. 68, FIG. 70, FIG. 72, FIG. 74, FIG. 76, FIG. 78, FIG. 80, FIG. 82, FIG. 84 and FIG. 86 illustrate cross-sectional surfaces corresponding to FIG. 6. FIG. 11, FIG. 13, FIG. 15, FIG. 17, FIG. 19, FIG. 21, FIG. 23, FIG. 25, FIG. 27, FIG. 29, FIG. 31, FIG. 33, FIG. 35, FIG. 37, FIG. 39, FIG. 41, FIG. 43, FIG. 45, FIG. 47, FIG. 49, FIG. 51, FIG. 53, FIG. 55, FIG. 57, FIG. 59, FIG. 61, FIG. 63, FIG. 65, FIG. 67, FIG. 69, FIG. 71, FIG. 73, FIG. 75, FIG. 77, FIG. 79, FIG. 81, FIG. 83 and FIG. 85 illustrate cross-sectional surfaces corresponding to FIG. 5. FIG. 12, FIG. 14, FIG. 16, FIG. 18, FIG. 20, FIG. 22, FIG. 24, FIG. 26, and FIG. 28 illustrate cross-sectional surfaces corresponding to FIG. 8.

In the manufacturing method, for example, as illustrated in FIG. 10, the plurality of insulating layers 103 and a plurality of sacrifice layers MLA are alternately formed. The sacrifice layer MLA, for example, contains silicon nitride (Si₃N₄) and the like. This process is, for example, performed by Chemical Vapor Deposition (CVD) or the like.

Next, for example, as illustrated in FIG. 11 and FIG. 12, an opening 115A is formed at a position corresponding to the insulating layer 115. An opening 116A is formed at a position corresponding to a part 116a of the insulating layer 116. The openings 115A, 116A extend in the Z-direction as illustrated in FIG. 12 and pass through the plurality of insulating layers 103 and the plurality of sacrifice layers MLA arranged in the Z-direction. This process is, for example, performed by RIE or the like.

Next, for example, as illustrated in FIG. 13 and FIG. 14, an insulating layer 115B is formed on an inner wall surface of the opening 115A. Additionally, an insulating layer 116B is formed on an inner wall surface of the opening 116A. The insulating layers 115B, 116B contain, for example, carbon (C) or the like. This process is, for example, performed by CVD or the like. Note that while the illustration is omitted, after forming the insulating layers 115B, 116B, an upper portion of the opening 116A is obstructed by an insulating layer or the like.

Next, for example, as illustrated in FIG. 15 and FIG. 16, in the insulating layer 115B, a part disposed at a proximity of an end portion of the opening 115A in the X-direction is removed. This process is, for example, performed by RIE or the like using a mask that covers a part other than the part disposed at the proximity of the end portion of the opening 115A in the X-direction in the insulating layer 115B and the insulating layer 116B.

Next, for example, as illustrated in FIG. 17 and FIG. 18, an opening 140A is formed at a position corresponding to the connection wiring 140. To an inside of the opening 140A, a part of an upper surface and a part of a lower surface of the insulating layer 103 and a part of side surfaces of the sacrifice layer MLA in the X-direction and the Y-direction are exposed. In this process, for example, a part of the sacrifice layer MLA is selectively removed via the opening 115A. This process is, for example, performed by wet etching or the like. Note that in this process, an upper portion of the opening 116A is obstructed by an insulating layer or the like. Therefore, the sacrifice layer MLA is not removed inside the opening 116A.

Next, for example, as illustrated in FIG. 19 and FIG. 20, a conductive layer 140B is formed on an inner wall surface of the opening 115A and the inside of the opening 140A. The opening 140A is embedded with the conductive layer 140B and the opening 115A is not embedded with the conductive layer 140B. This process is, for example, performed by CVD or the like. Note that in this process, an upper portion of the opening 116A is obstructed by an insulating layer or the like. Therefore, the conductive layer 140B is not formed on an inside of the opening 116A.

Next, for example, as illustrated in FIG. 21 and FIG. 22, the connection wiring 140 is formed. In this process, for example, the part of the conductive layer 140B disposed on the inner wall surface of the opening 115A is removed to separate the conductive layer 140B in the Z-direction. This process is, for example, performed by wet etching or the like. Note that while the illustration is omitted, after forming the connection wiring 140, the insulating layer on the upper portion of the opening 116A and the like are removed to communicate the opening 116A with outside.

Next, for example, as illustrated in FIG. 23 and FIG. 24, the insulating layers 115B, 116B are removed. This process is, for example, performed by wet etching or the like.

Next, for example, as illustrated in FIG. 25 and FIG. 26, an opening 104A is formed at a position corresponding to the via-wiring 104. As illustrated in FIG. 26, the opening 104A extends in the Z-direction and passes through the plurality of insulating layers 103 and the plurality of sacrifice layers MLA arranged in the Z-direction. This process is, for example, performed by RIE or the like.

Next, for example, as illustrated in FIG. 27 and FIG. 28, insulating layers 115C, 116C and an insulating layer 104C are formed on inner wall surfaces of the openings 115A, 116A and an inner peripheral surface of the opening 104A. The insulating layers 115C, 116C and the insulating layer 104C, for example, contain silicon oxide (SiO₂) or the like. This process is, for example, performed by CVD or the like.

Next, for example, as illustrated in FIG. 29 and FIG. 30, an opening 101A is formed at a proximity of a position corresponding to the conductive layer 120. The opening 101A extends in the Y-direction and the Z-direction, passes through the plurality of insulating layers 103 and the plurality of sacrifice layers MLA arranged in the Z-direction, and separate these configurations in the X-direction. This process is, for example, performed by RIE or the like.

Next, for example, as illustrated in FIG. 31 and FIG. 32, an opening 120A is formed at a position corresponding to the conductive layer 120. To an inside of the opening 120A, a part of an upper surface and a part of the lower surface of the insulating layer 103, a part of a side surface of the sacrifice layer MLA in the X-direction, a part of side surfaces of the connection wiring 140 in the X-direction and the Y-direction, a part of side surfaces of the insulating layer 116C in the X-direction and the Y-direction, and a part of an outer peripheral surface of the insulating layer 104C are exposed. In this process, for example, via the opening 101A, a part of the sacrifice layer MLA is selectively removed. This process is, for example, performed by wet etching or the like.

Next, for example, as illustrated in FIG. 33 and FIG. 34, a sacrifice layer 101B, such as silicon (Si), is embedded into the inner wall surface of the opening 101A and the inside of the opening 120. The opening 120A is embedded with the sacrifice layer 101B and the opening 101A is not embedded with the sacrifice layer 101B. This process is, for example, performed by CVD or the like.

Next, for example, as illustrated in and FIG. 35 and FIG. 36, to an inside of the opening 101A and the inside of the opening 120A, sacrifice layers 101C, such as silicon nitride (SiN), are formed. In this process, for example, by wet etching or the like via the opening 101A, a part of the sacrifice layer 101B is removed and a side surface of the connection wiring 140 in the X-direction is exposed. The sacrifice layer 101C is formed by CVD or the like.

Next, for example, as illustrated in FIG. 37 and FIG. 38, the insulating layers 115C, 116C are removed. Additionally, the sacrifice layer 101B is removed to form an opening 116D at a position corresponding to the part 116b of the insulating layer 116. This process is, for example, performed by wet etching or the like.

Next, for example, as illustrated in FIG. 39 and FIG. 40, the insulating layer 115 is formed on an inside of the opening 115A. The insulating layer 116 is formed on insides of the openings 116A, 116D. This process is, for example, performed by CVD or the like.

Next, for example, as illustrated in FIG. 41 and FIG. 42, the insulating layer 104C is removed. This process is, for example, performed by wet etching or the like.

Next, for example, as illustrated in FIG. 43 and FIG. 44, an opening 111A is formed at a position corresponding to the semiconductor layer 111. To an inside of the opening 111A, a part of the upper surface and a part of the lower surface of the insulating layer 103, a part of the side surface of the sacrifice layer MLA in the X-direction, a part of a side surface of the insulating layer 115 in the Y-direction, and a part of side surfaces of the insulating layer 116 in the Y-direction and the X-direction are exposed. In this process, for example, a part of the sacrifice layer MLA is selectively removed via the opening 104A. This process is, for example, performed by wet etching or the like.

Next, for example, as illustrated in FIG. 45 and FIG. 46, to the insides of the opening 111A and the opening 104A, a conductive layer 113A and a sacrifice layer 111B, such as silicon (Si), are formed. The conductive layer 113A is formed on a part of the upper surface, a part of the lower surface, and an exposed surface to the opening 104A of the insulating layer 103, a part of the side surface of the sacrifice layer MLA in the X-direction, a part of the side surface of the insulating layer 115 in the Y-direction, and a part of the side surfaces of the insulating layer 116 in the Y-direction and the X-direction. The opening 111A is embedded with the sacrifice layer 111B and the opening 104A is not embedded with the sacrifice layer 111B. This process is, for example, performed by CVD or the like. Note that while the illustration is omitted, after forming the conductive layer 113A and the sacrifice layer 111B, the upper portion of the opening 104A is obstructed by the insulating layer or the like.

Next, for example, as illustrated in FIG. 47 and FIG. 48, an opening 102A is formed at a position corresponding to the conductive layer 102. The opening 102A extends in the Y-direction and the Z-direction, passes through the plurality of insulating layers 103 and the plurality of sacrifice layers MLA arranged in the Z-direction, the insulating layer 115, and the insulating layer 116, and separates these configurations in the X-direction. This process is, for example, performed by RIE or the like.

Next, for example, as illustrated in FIG. 49 and FIG. 50, an opening 130A is formed at a position corresponding to the capacitor structure 130. In this process, the sacrifice layer MLA is removed via the opening 102A. Additionally, in the conductive layer 113A, a part covering a side surface of the sacrifice layer 111B on one side (on an opening 102A side) in the X-direction is removed. In this process, the side surface of the sacrifice layer 111B in the X-direction is exposed to an inside of the opening 102A. This process is, for example, performed by wet etching or the like.

Next, for example, as illustrated in FIG. 51 and FIG. 52, via the opening 102A and the opening 130A, an oxidation process is performed on the sacrifice layer 111B to form an insulating layer 111C. A sacrifice layer 130B, such as silicon (Si), is embedded into the opening 102A and the opening 130A. This process is, for example, performed by CVD or the like.

Next, for example, as illustrated in FIG. 53 and FIG. 54, the conductive layer 113 is formed. In this process, for example, in the sacrifice layer 111B, a part disposed on the inner peripheral surface of the opening 104A is removed. Next, in the conductive layer 113A, a part disposed on the inner peripheral surface of the opening 104A is removed and the conductive layer 113A is separated in the Z-direction. This process is, for example, performed by wet etching or the like.

Next, for example, as illustrated in FIG. 55 and FIG. 56, the sacrifice layer 111B is removed. This process is, for example, performed by wet etching or the like.

Next, for example, as illustrated in FIG. 57 and FIG. 58, the insulating layer 111C and a part of the sacrifice layer 130B are removed. This process is, for example, performed by wet etching or the like.

Next, for example, as illustrated in FIG. 59 and FIG. 60, an insulating layer 112A and the sacrifice layer 111B are formed on the insides of the opening 111A and the opening 104A. The insulating layer 112A is formed on an upper surface, a lower surface, and an exposed surface to the opening 111A of the conductive layer 113, a part of an upper surface, a part of a lower surface, and an exposed surface to the opening 104A of the insulating layer 103, a part of a side surface of the sacrifice layer 130B in the X-direction, a part of the side surface of the insulating layer 115 in the Y-direction, and a part of the side surfaces of the insulating layer 116 in the Y-direction and the X-direction. The opening 111A is embedded with the sacrifice layer 111B and the opening 104A is not embedded with the sacrifice layer 111B. This process is, for example, performed by CVD or the like. Note that while the illustration is omitted, after forming the insulating layer 112A and the sacrifice layer 111B, the upper portion of the opening 104A is obstructed by the insulating layer or the like.

Next, for example, as illustrated in FIG. 61 and FIG. 62, the sacrifice layer 130B is removed. This process is, for example, performed by wet etching or the like.

Next, for example, as illustrated in FIG. 63 and FIG. 64, the insulating layer 112 is formed. In this process, via the opening 102A and the opening 130A, in the insulating layer 112A, a part covering a side surface of the sacrifice layer 111B on one side (on the opening 102A side) in the X-direction is removed. In this process, the side surface of the sacrifice layer 111B in the X-direction is exposed to the inside of the opening 102A. This process is, for example, performed by wet etching or the like.

Next, for example, as illustrated in FIG. 65 and FIG. 66, via the opening 102A and the opening 130A, a conductive layer 134A is formed on a side surface of the sacrifice layer 111B on one side (on the opening 102A side) in the X-direction, a side surface on one side (on the opening 102A side) in the X-direction and both side surfaces in the Y-direction of the insulating layer 115, a side surface on one side in the X-direction (on the opening 102A side) and both side surfaces in the Y-direction of the insulating layer 116, and an upper surface, a lower surface, and a side surface on one side in the X-direction (the opening 102A side) of the insulating layer 103. This process is, for example, performed by Atomic Layer Deposition (ALD) or the like.

Next, for example, as illustrated in FIG. 67 and FIG. 68, a sacrifice layer 130C, such as silicon (Si), is formed on the inside of the opening 102A. The opening 130A is embedded with the sacrifice layer 130C and the opening 102A is not embedded with the sacrifice layer 130C. This process is, for example, performed by CVD or the like.

Next, for example, as illustrated in FIG. 69 and FIG. 70, via the opening 102A, a part of the sacrifice layer 130C is removed. In this process, for example, parts of the conductive layer 134A disposed on side surfaces of the insulating layers 115, 116 and the insulating layer 103 in the X-direction are exposed. This process is, for example, performed by wet etching or the like.

Next, for example, as illustrated in FIG. 71 and FIG. 72, the conductive layer 134 is formed. In this process, for example, a part of the conductive layer 134A disposed on side surfaces of the insulating layers 115, 116 and the insulating layer 103 in the X-direction is removed to separate the conductive layer 134A in the Y-direction and the Z-direction. This process is, for example, performed by wet etching or the like.

Next, for example, as illustrated in FIG. 73 and FIG. 74, the sacrifice layer 130C is removed. This process is, for example, performed by wet etching or the like.

Next, for example, as illustrated in FIG. 75 and FIG. 76, via the opening 102A, a part of the insulating layers 115, 116 and a part of the insulating layer 103 are removed to form an opening 130D. In the illustrated example, a region inside the conductive layer 134 is indicated as the opening 130A and a region outside the conductive layer 134 is indicated as the opening 130D. In this process, the insulating layers 115, 116 and the insulating layers 103 are removed in a range that the conductive layer 113 is not exposed to the opening 130D. This process is, for example, performed by wet etching or the like.

Next, for example, as illustrated in FIG. 77 and FIG. 78, via the opening 130A, the opening 130D, and the opening 102A, the insulating layers 133, 135, the conductive layers 132, 136, and the conductive layer 131, 137, 102 are formed on an upper surface, a lower surface, a side surface on one side (on the opening 102A side) in the X-direction, and both side surfaces in the Y-direction of the conductive layer 134. This process is, for example, performed by CVD or the like.

Next, for example, as illustrated in FIG. 79 and FIG. 80, the sacrifice layer 111B is removed. This process is, for example, performed by wet etching or the like.

Next, for example, as illustrated in FIG. 81 and FIG. 82, the semiconductor layer 111 is formed on the insides of the opening 111A and the opening 104A. The opening 111A is embedded with the semiconductor layer 111. The opening 104A is not embedded with the semiconductor layer 111. This process is, for example, performed by ALD or the like.

Next, for example, as illustrated in FIG. 83 and FIG. 84, the via-wiring 104 is formed on the inside of the opening 104A. This process is, for example, performed by ALD, CVD, and the like.

Next, for example, as illustrated in FIG. 85 and FIG. 86, the sacrifice layer 101C is removed. This process is, for example, performed by wet etching or the like.

Afterwards, for example, as illustrated in FIG. 5 and FIG. 6, the conductive layer 120 is formed on the inside of the opening 120A. This process is, for example, performed by CVD or the like.

### Effects

The semiconductor memory device according to the embodiment includes the plurality of memory layers ML arranged in the Z-direction and the via-wiring 104 extending in the Z-direction. The plurality of memory layers ML each include the transistor structure 110, the capacitor structure 130 disposed on one side with respect to the transistor structure 110 in the X-direction, and the conductive layer 120 disposed on the other side with respect to the transistor structure 110 in the X-direction.

Even when the number of memory layers ML included in the memory cell array MCA increases, such a configuration is manufacturable without the increase in the number of processes except for the stacking process (the process described with reference to FIG. 10). Therefore, increasing high integration can be comparatively easily achieved.

In the transistor structure 110 according to the embodiment, the conductive layer 113 is opposed to the upper surface and the lower surface of the semiconductor layer 111.

In such a configuration, an interference of an electric field between the plurality of semiconductor layers 111 arranged in the Z-direction can be reduced. Therefore, even when increasing high integration of the memory cell array MCA in the Z-direction is achieved, the semiconductor layer 111 can be preferably controlled to an ON state or an OFF state, and the semiconductor memory device that preferably operates can be provided.

When the transistor TrC is set to an ON state, channels are formed on an upper surface, a lower surface, and both side surfaces in the Y-direction of the semiconductor layer 111. Therefore, an ON current of the transistor TrC can be comparatively increased. Thus, the operation can be high speed and stabilized.

Here, for example, it is conceivable that the wiring functioning as the word line WL (the wiring extending in the Y-direction) is disposed between the via-wiring 104 and the capacitor structure 130, and a part of the wiring functioning as the word line WL is used as the gate electrode of the transistor TrC. However, in such a structure, the semiconductor layer functioning as the channel region of the transistor TrC intersects with the wiring functioning as the word line WL as viewed from the Z-direction. Therefore, for example, without separating the semiconductor layer in the X-direction, the wiring extending in the Y-direction needs to be processed, and a degree of difficulty of manufacturing is high. Additionally, a width of the memory layer in the Z-direction increases.

In this respect, in the embodiment, the conductive layer 120 that functions as the word line WL is disposed on the side opposite to the plate line PL with respect to the transistor structure 110 and is disposed at a position not overlapping with the transistor structure 110 as viewed from the Z-direction. Therefore, the conductive layer 120 and the transistor structure 110 can be independently formed and manufacturing can be comparatively easily performed. While a width of the memory layer ML in the Z-direction is reduced, a wiring resistance of the conductive layer 120 can be a comparatively small value.

In such a configuration, the via-wiring 104 that functions as the bit line BL and the conductive layer 113 that functions as the gate electrode of the transistor TrC are opposed via the insulating layer 112. Therefore, parasitic capacitance occurs between the bit line BL and the gate electrode of the transistor TrC. Here, when the parasitic capacitance of the bit line BL is large, the above-described sense amplifier circuit cannot preferably detect electric charge accumulated in the capacitor CpC, and there may be a case where the read operation cannot be preferably performed. Therefore, to preferably perform the read operation in such a configuration, for example, it is considered that an opposed area of the via-wiring 104 and the conductive layer 113 is reduced and an electrostatic capacity between the bit line BL and the gate electrode of the transistor TrC is reduced.

In such a configuration, parasitic capacitance occurs between two conductive layers 113 adjacent in the Z-direction. Here, when the parasitic capacitance between the two conductive layers 113 adjacent in the Z-direction is large, in the read operation and a write operation, an operation speed becomes slow in some cases. Therefore, an area of the conductive layer 113 in the X-Y cross-sectional surface is preferably small.

Therefore, the semiconductor memory device according to the embodiment, as described with reference to FIG. 7, employs a configuration in which the part S1 of the outer peripheral surface of the via-wiring 104 is opposed to the conductive layer 113 and the other part (the other part S2) is not opposed to the conductive layer 113. With such a configuration, the opposed surface area between the via-wiring 104 and the conductive layer 113 can be reduced and the parasitic capacitance between the via-wiring 104 and the conductive layer 113 can be reduced. Additionally, the area in the X-Y cross-sectional surface of the conductive layer 113 can be reduced and the parasitic capacitance between the conductive layers 113 arranged in the Z-direction can be reduced.

In the embodiment, a distance between the conductive layer 120 and the via-wiring 104 is larger than a distance between the conductive layer 113 and the via-wiring 104. Therefore, the parasitic capacitance between the bit line BL and the word line WL can also be reduced.

In such a configuration, in the process described with reference to FIG. 17 and FIG. 18, the opening 140A is formed at the position corresponding to the connection wiring 140. Here, since the opening 140A is formed by wet etching or the like, an amount of removal of the sacrifice layer MLA is uniformed to be an approximately constant size from one side to the other side in the Z-direction comparatively easily. Here, the connection wiring 140 is mainly formed from the part formed on the inside of the opening 140A in the conductive layer 140B formed in the process described with reference to FIG. 19 and FIG. 20. Therefore, a width of the part 141 of the connection wiring 140 in the Y-direction and a width of the part 142 of the connection wiring 140 in the X-direction are approximately defined by the amount of removal of the sacrifice layer MLA in the process described with reference to FIG. 17 and FIG. 18. Therefore, in the embodiment, the width of the part 141 of the connection wiring 140 in the Y-direction and the width of the part 142 of the connection wiring 140 in the X-direction are also uniformed to an approximately constant size from one side to the other side in the Z-direction comparatively easily.

Here, for example, when these two widths significantly vary from one side to the other side in the Z-direction, in a case where these two widths are decreased, the connection wiring 140 is disconnected in a part of the memory layers ML, and the conductive layer 120 and the conductive layer 113 cannot be reliably connected. Therefore, to reliably connect the conductive layer 120 and the conductive layer 113, these two widths need to be increased. However, when these two widths are increased, an electrostatic capacity between the two connection wirings 140 adjacent in the Z-direction increases.

In this respect, in the embodiment, as described above, the width of the part 141 of the connection wiring 140 in the Y-direction and the width of the part 142 of the connection wiring 140 in the X-direction are uniformed to be the approximately constant size from one side to the other side in the Z-direction comparatively easily. Therefore, even when a wiring width of the connection wiring 140 has a comparatively small size, from one side to the other side in the Z-direction, the connection wiring 140 can be preferably formed. Thus, the parasitic capacitance between the two connection wirings 140 adjacent in the Z-direction can be reduced to a comparatively small value.

Additionally, in such a configuration, the configurations in the transistor structure 110 (the semiconductor layer 111, the insulating layer 112, and the conductive layer 113) includes the arc-shaped side surfaces extending along the outer peripheral surface of the via-wiring 104 and the arc-shaped side surfaces extending along the circle with the center position of the via-wiring 104 as the center. In such a configuration, since a distance between a connecting part of the semiconductor layer 111 with the via-wiring 104 and a connecting part of the semiconductor layer 111 with the capacitor structure 130 becomes an approximately constant, sizes of the transistor structure 110 in the X-direction and the Y-direction are minimally reduced while an OFF leakage current in the transistor structure 110 can be reduced.

### Second Embodiment

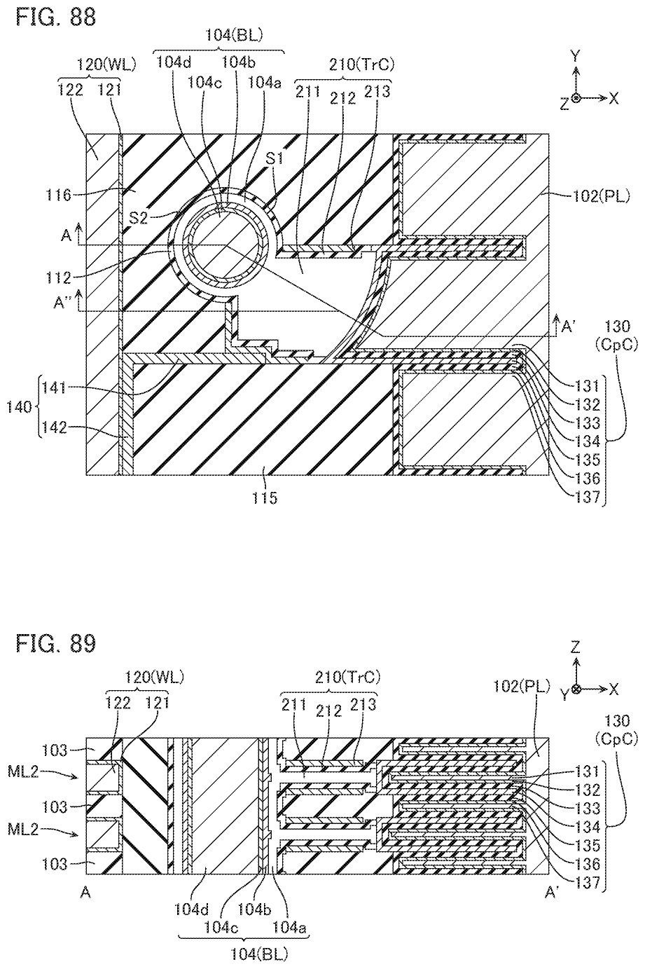

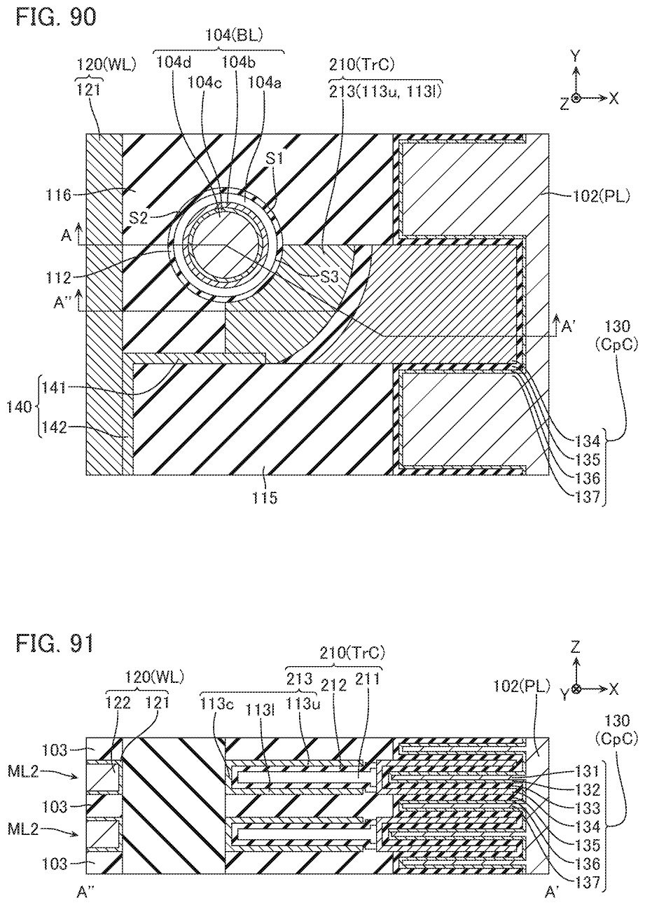

FIG. 87 is a schematic X-Y cross-sectional view illustrating a configuration of a part of a semiconductor memory device according to the second embodiment. FIG. 88 and FIG. 90 are schematic X-Y cross-sectional views illustrating configurations of part of the semiconductor memory device. FIG. 88 illustrates an X-Y cross-sectional surface at a height position (a position in the Z-direction) corresponding to a semiconductor layer 211 described later. Additionally, FIG. 90 illustrates an X-Y cross-sectional surface at a height position (the position in the Z-direction) corresponding to the part 113u or the part 113l of a conductive layer 213 described later. FIG. 89 is a schematic cross-sectional view illustrating a configuration of a part of the semiconductor memory device and illustrates a configuration of the structure illustrated in FIG. 88 and FIG. 90 taken along the line A-A′ and viewed along the arrow direction. FIG. 91 is a schematic cross-sectional view illustrating a configuration of a part of the semiconductor memory device and illustrates a configuration of the structure illustrated in FIG. 88 and FIG. 90 taken along the line A″-A′ and viewed along the arrow direction.

The semiconductor memory device according to the second embodiment is basically configured similarly to the semiconductor memory device according to the first embodiment. However, the semiconductor memory device according to the second embodiment includes a plurality of memory layers ML2 instead of the plurality of memory layers ML. The memory layer ML2 is basically configured similarly to the memory layer ML. However, the memory layer ML2 includes a transistor structure 210 instead of the transistor structure 110.

The transistor structure 210 includes the semiconductor layer 211, an insulating layer 212, and the conductive layer 213. The semiconductor layer 211, the insulating layer 212, and the conductive layer 213 are basically configured similarly to the semiconductor layer 111, the insulating layer 112, and the conductive layer 113. However, as described with reference to FIG. 5 and FIG. 7, the center position of the semiconductor layer 111, the insulating layer 112, and the conductive layer 113 in the Y-direction approximately matches the center position of the corresponding via-wiring 104 in the Y-direction. On the other hand, the center position of the semiconductor layer 211, the insulating layer 212, and the conductive layer 213 in the Y-direction does not approximately match the center position of the corresponding via-wiring 104 in the Y-direction.

For example, in the example of FIG. 88, the semiconductor film 104a in the via-wiring 104 is continuous with a side surface of the semiconductor layer 211 on one side in the Y-direction (an insulating layer 116 side) and is spaced from a side surface of the semiconductor layer 211 on the other side in the Y-direction (an insulating layer 115 side). In the illustrated example, the via-wiring 104 is continuous with the semiconductor layer 211 in the degree range of approximately 90°.

In the example of FIG. 90, the via-wiring 104 is close to a side surface of the conductive layer 213 on one side (the insulating layer 116 side) in the Y-direction and spaced from a side surface of the conductive layer 213 on the other side (the insulating layer 115 side) in the Y-direction. In the illustrated example, the via-wiring 104 is opposed to the conductive layer 213 in the degree range of approximately 90°.

According to such a configuration, an electrostatic capacity between the bit line BL and the gate electrode of the transistor TrC can be further reduced. A parasitic capacitance between the gate electrodes of the two transistors TrC arranged in the Z-direction can be further reduced.

### Third Embodiment

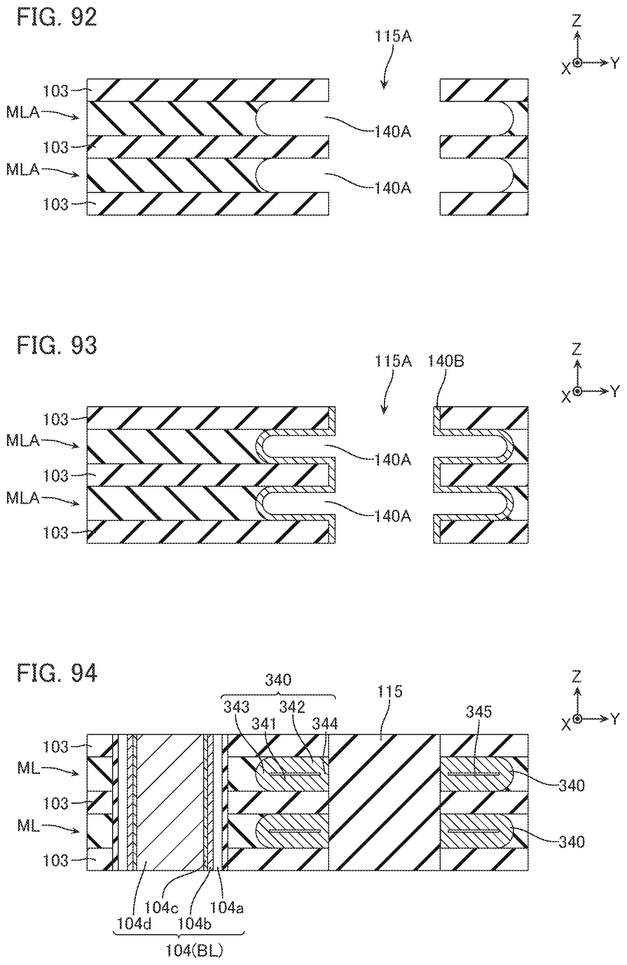

FIG. 92 and FIG. 93 are schematic cross-sectional views for describing a manufacturing method of the semiconductor memory device according to a third embodiment. FIG. 92 illustrates a cross-sectional surface of a position corresponding to a part of FIG. 18 in the process described with reference to FIG. 17 and FIG. 18. FIG. 93 illustrates a cross-sectional surface of a position corresponding to a part of FIG. 20 in the process described with reference to FIG. 19 and FIG. 20.

In manufacturing the semiconductor memory device according to the first embodiment, as described with reference to FIG. 17 and FIG. 18, the opening 140A is formed. FIG. 92 illustrates a drawing of this opening 140A being formed to a further deep position. Additionally, as described with reference to FIG. 19 and FIG. 20, the conductive layer 140B is formed on the inner wall surface of the opening 115A and the inside of the opening 140A. FIG. 93 illustrates a drawing in which the conductive layer 140B is formed to the extent that the opening 140A is not embedded.

Here, the conductive layer 140B is formed on the upper surface and the lower surface of the insulating layer 103 in the inside of the opening 140A. As this process proceeds, a thickness of the conductive layer 140B in the Z-direction increases and a gas used for film formation is less likely to get into the inside of the opening 140A in some cases. Additionally, before the opening 140A is embedded with the conductive layer 140B, the opening 140A is obstructed, and a cavity is formed on an inside of the connection wiring 140 in some cases.

Hereinafter, as a semiconductor memory device according to the third embodiment, such a structure is exemplified.

FIG. 94 is a schematic cross-sectional view illustrating a configuration of a part of the semiconductor memory device according to the third embodiment. FIG. 94 illustrates a cross-sectional surface of a position corresponding to a part of FIG. 8. The semiconductor memory device according to the third embodiment is basically manufactured similarly to the semiconductor memory device according to the first embodiment or the second embodiment. However, in manufacturing the semiconductor memory device according to the third embodiment, in the description with reference to FIG. 17 and FIG. 18, the opening 140A is formed to a position of a degree illustrated in FIG. 92. Additionally, the semiconductor memory device according to the third embodiment is basically configured similarly to the semiconductor memory device according to the first embodiment or the second embodiment. However, the semiconductor memory device according to the third embodiment includes a connection wiring 340 instead of the connection wiring 140.

The connection wiring 340 is basically configured similarly to the connection wiring 140. However, as exemplified in FIG. 94, the connection wiring 340 includes two parts 341, 342 arranged in the Z-direction, a part 343 disposed on a side opposite to the insulating layer 115 with respect to these two parts 341, 342, and a part 344 disposed on the insulating layer 115 side with respect to these two parts 341, 342. A lower surface of the part 341 matches a lower surface of the connection wiring 340 and is in contact with an upper surface of the insulating layer 103. An upper surface of the part 342 matches an upper surface of the connection wiring 340 and is in contact with the lower surface of the insulating layer 103. The part 343 is continuous with the parts 341, 342. Although the illustration is omitted, an end portion of the part 343 on one side (on the conductive layer 120 side) in the X-direction matches an end portion of the connection wiring 340 on one side (on the conductive layer 120 side) in the X-direction and is connected to the conductive layer 120. The part 344 is continuous with the parts 341, 342. End portions of the part 344 on one side (on the insulating layer 115 side) in the X-direction and the Y-direction match end portions of the connection wiring 340 on one side (on the insulating layer 115 side) in the X-direction and the Y-direction and are connected to the insulating layer 115.

In the third embodiment, a cavity 345 is disposed in a region between the parts 341, 342.

### Fourth Embodiment

In manufacturing the semiconductor memory device according to the third embodiment, in the process described with reference to FIG. 93, the formation of the conductive layer 140B is continued until the opening 140A is obstructed. However, such a method is merely an example, and the formation of the conductive layer 140B may be terminated before the opening 140A is obstructed. Additionally, another material may be formed in the opening 140A.

Hereinafter, as a semiconductor memory device according to the fourth embodiment, such a structure is exemplified.

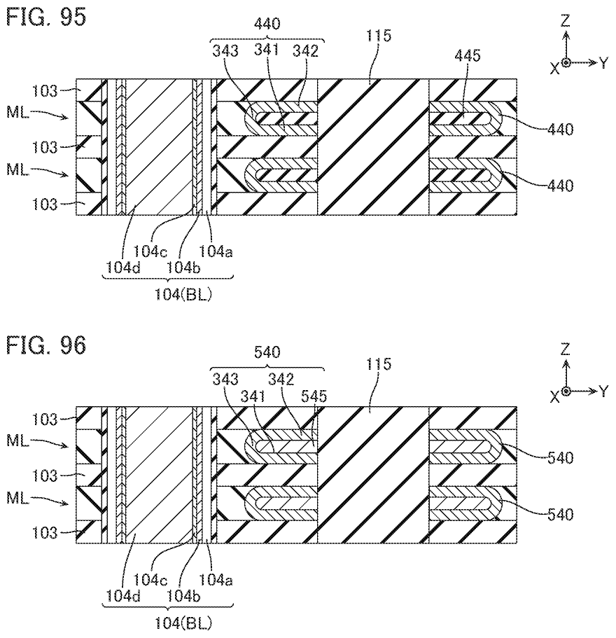

FIG. 95 is a schematic cross-sectional view illustrating a configuration of a part of the semiconductor memory device according to the fourth embodiment. FIG. 95 illustrates a cross-sectional surface of a position corresponding to FIG. 94. The semiconductor memory device according to the fourth embodiment is basically configured similarly to the semiconductor memory device according to the third embodiment. However, the semiconductor memory device according to the fourth embodiment includes a connection wiring 440 instead of the connection wiring 340.

The connection wiring 440 is basically configured similarly to the connection wiring 340. However, the connection wiring 440 does not include the part 344.

Additionally, in the fourth embodiment, in a region between the parts 341, 342, an insulating layer 445, such as silicon oxide (SiO₂), is disposed.

### Fifth Embodiment

In manufacturing the semiconductor memory device according to the fourth embodiment, after forming the conductive layer 140B, the insulating layer 445 is formed in the opening 140A. However, such a method is merely an example. For example, after forming the conductive layer 140B, a conductive layer may be formed in the opening 140A.

Hereinafter, as a semiconductor memory device according to the fifth embodiment, such a structure is exemplified.

FIG. 96 is a schematic cross-sectional view illustrating a configuration of a part of the semiconductor memory device according to the fifth embodiment. FIG. 96 illustrates a cross-sectional surface of a position corresponding to FIG. 95. The semiconductor memory device according to the fifth embodiment is basically configured similarly to the semiconductor memory device according to the fourth embodiment. However, the semiconductor memory device according to the fifth embodiment includes a connection wiring 540 instead of the connection wiring 440.

The connection wiring 540 is basically configured similarly to the connection wiring 440. However, the connection wiring 540 includes a conductive layer 545 disposed in a region between the parts 341, 342. The conductive layer 545, for example, may contain tungsten (W).

### Sixth Embodiment

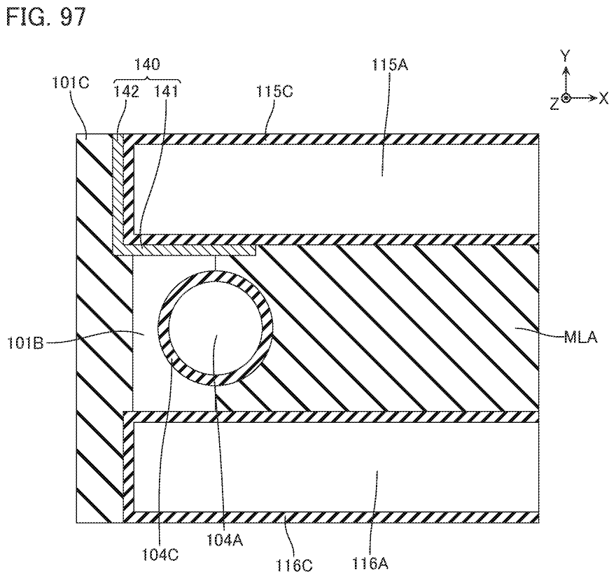

FIG. 97 is a schematic cross-sectional view for describing the manufacturing method of a semiconductor memory device according to the sixth embodiment.

In manufacturing the semiconductor memory device according to the first embodiment, in the process described with reference to FIG. 35 and FIG. 36, a part of the sacrifice layer 101B is removed and the side surface of the connection wiring 140 in the X-direction is exposed. In this process, not only the side surface of the connection wiring 140 in the X-direction, but also a part of a side surface in the Y-direction may be exposed. Thus, the side surface of the connection wiring 140 in the X-direction is exposed with more certainty and a yield of the semiconductor memory device can be improved.

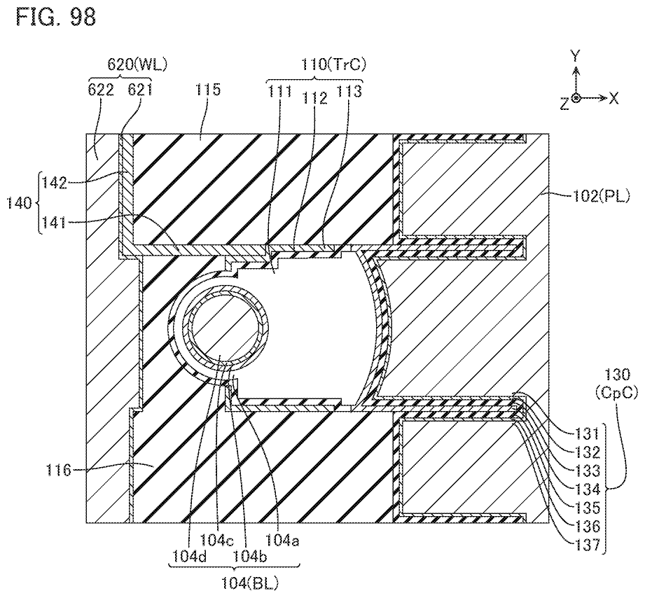

FIG. 98 is a schematic X-Y cross-sectional view illustrating a configuration of a part of the semiconductor memory device according to the sixth embodiment. The semiconductor memory device according to the sixth embodiment is basically configured similarly to the semiconductor memory device according to the first embodiment or the second embodiment. However, the semiconductor memory device according to the sixth embodiment includes a conductive layer 620 instead of the conductive layer 120.

The conductive layer 620 is basically configured similarly to the conductive layer 120. However, the conductive layer 620 is connected to a part of a side surface of the connection wiring 140 in the Y-direction, in addition to the side surface of the connection wiring 140 in the X-direction. The conductive layer 620, for example, includes a barrier conductive film 621 and a conductive film 622. The barrier conductive film 621 and the conductive film 622 are basically configured similarly to the barrier conductive film 121 and the conductive film 122. However, in manufacturing of the sixth embodiment, in the process corresponding to FIG. 97, not only the side surface of the connection wiring 140 in the X-direction, but also a part of the side surface in the Y-direction is also exposed. Additionally, a side surface in the X-direction and a part of a side surface in the Y-direction of the insulating layer 116C are also exposed. In view of this, a step is formed between the side surface of the connection wiring 140 in the X-direction and the side surface of the sacrifice layer 101B in the X-direction. Similarly, a step is also formed between the side surface of the insulating layer 116C in the X-direction and the side surface of the sacrifice layer 101B in the X-direction. The barrier conductive film 621 and the conductive film 622 are formed along these steps.

### Other Embodiments

The semiconductor memory devices according to the first embodiment and the sixth embodiment are described above. However, the semiconductor memory devices according to these embodiments are merely examples, and specific configurations and the like are appropriately adjustable.

For example, the semiconductor memory device according to the second embodiment may include the connection wiring 340 (FIG. 94), the connection wiring 440 (FIG. 95), or the connection wiring 540 (FIG. 96) instead of the connection wiring 140. The semiconductor memory device according to the second embodiment may include the conductive layer 620 (FIG. 98) instead of the conductive layer 120.

In the semiconductor memory devices according to the first embodiment to the sixth embodiment, the via-wiring 104 that functions as the bit line contains the conductive oxide, such as indium tin oxide (ITO). However, such a conductive oxide may be contained in the transistor structure 110, 210, not the via-wiring 104 extending in the Z-direction. The via-wiring 104 and the transistor structure 110, 210 may contain another material or the like.

In the above description, the example in which the capacitor CpC is employed as a memory portion connected to the transistor structure 110 is described. However, the memory portion need not be the capacitor CpC. For example, the memory portion may contain a ferroelectric material, a ferromagnet material, a chalcogen material such as GeSbTe, or another material and data may be stored using characteristics of these materials. For example, in any of the structures described above, any of these materials may be contained in the insulating layer between the electrodes forming the capacitors CpC.

Manufacturing methods of the semiconductor memory devices according to the first embodiment to the sixth embodiment are also appropriately adjustable. For example, orders of any two of the processes described above may be interchanged or any two of the processes described above may be simultaneously performed.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a plurality of memory layers arranged in a first direction intersecting with a surface of the substrate; and
a first via-wiring extending in the first direction, wherein
the plurality of memory layers each include:
a first semiconductor layer electrically connected to the first via-wiring;
a first gate electrode opposed to surfaces of the first semiconductor layer on one side and the other side in the first direction;
a first memory portion disposed on one side in a second direction intersecting with the first direction with respect to the first semiconductor layer and electrically connected to the first semiconductor layer;
a first wiring disposed on the other side in the second direction with respect to the first semiconductor layer, electrically connected to the first gate electrode, and extending in a third direction intersecting with the first direction and the second direction; and
a connection wiring connected to the first gate electrode and the first wiring, and
the connection wiring includes:
a first part extending in the second direction along a side surface of the first gate electrode on one side in the third direction and connected to the side surface of the first gate electrode on the one side in the third direction; and
a second part continuous with the first part, extending in the third direction along a side surface of the first wiring on a first via-wiring side in the second direction, and connected to the side surface of the first wiring on the first via-wiring side in the second direction.

2. The semiconductor memory device according to claim 1, further comprising
a second via-wiring arranged with the first via-wiring in the third direction and extending in the first direction, wherein
the plurality of memory layers each include:
a second semiconductor layer electrically connected to the second via-wiring;
a second gate electrode opposed to surfaces of the second semiconductor layer on one side and on the other side in the first direction; and
a second memory portion disposed on one side in the second direction with respect to the second semiconductor layer and electrically connected to the second semiconductor layer, and
the connection wiring includes a third part continuous with the second part, extending in the second direction along a side surface of the second gate electrode on the other side in the third direction, and connected to the side surface of the second gate electrode on the other side in the third direction.

3. The semiconductor memory device according to claim 1, wherein
a length of the connection wiring in the first direction matches a length of the first gate electrode in the first direction.

4. The semiconductor memory device according to claim 1, wherein
a length of the connection wiring in the first direction matches a length of the first wiring in the first direction.

5. The semiconductor memory device according to claim 1, wherein
the connection wiring includes:
a fourth part and a fifth part arranged in the first direction and spaced from each other in the first direction; and
a sixth part continuous with the fourth part and the fifth part.

6. The semiconductor memory device according to claim 5, wherein
a cavity is disposed between the fourth part and the fifth part.

7. The semiconductor memory device according to claim 5, wherein
an insulating layer is disposed between the fourth part and the fifth part.

8. The semiconductor memory device according to claim 5, wherein
a conductive layer is disposed between the fourth part and the fifth part.

9. The semiconductor memory device according to claim 1, wherein
the first gate electrode includes a first part opposed to the surface of the first semiconductor layer on the one side in the first direction and a second part opposed to the surface of the first semiconductor layer on the other side in the first direction, and
in a cross-sectional surface perpendicular to the first direction and including a part of the first part or the second part of the first gate electrode corresponding to one of the plurality of memory layers, the first via-wiring includes a first surface opposed to the first gate electrode and a second surface not opposed to the first gate electrode.

10. The semiconductor memory device according to claim 9, further comprising
a gate insulating film disposed between the first semiconductor layer and the first gate electrode, wherein
in the cross-sectional surface, the first gate electrode is opposed to the first surface of the first via-wiring via the gate insulating film.

11. The semiconductor memory device according to claim 9, wherein
in the cross-sectional surface, a surface of the first gate electrode on a first memory portion side is a curved surface along a circle around a center point of the first via-wiring.

12. The semiconductor memory device according to claim 9, wherein
in the cross-sectional surface, a surface of the first gate electrode on the first via-wiring side is a curved surface along a circle around a center point of the first via-wiring.

13. The semiconductor memory device according to claim 9, wherein
in the cross-sectional surface,
a surface of the first gate electrode on a first memory portion side is a curved surface along a first circle around a center point of the first via-wiring,
a surface of the first gate electrode on the first via-wiring side is a curved surface along a second circle around the center point of the first via-wiring, and
a radius of the first circle is larger than a radius of the second circle.

14. The semiconductor memory device according to claim 9, wherein
in a cross-sectional surface perpendicular to the first direction and including a part of the first semiconductor layer corresponding to one of the plurality of memory layers, a surface of the first semiconductor layer on a first memory portion side is a curved surface along a circle around a center point of the first via-wiring.

15. The semiconductor memory device according to claim 1, wherein
the first via-wiring includes a conductive member extending in the first direction and a semiconductor film extending along an outer peripheral surface of the conductive member in the first direction,
in a cross-sectional surface perpendicular to the first direction and including a part of the first semiconductor layer corresponding to one of the plurality of memory layers;
a surface of the first semiconductor layer on a first memory portion side is a curved surface along a first circle around a center point of the first via-wiring;
the first semiconductor layer is continuous with the semiconductor film;
a surface of the semiconductor film on a first wiring side is a curved surface along a second circle around the center point of the first via-wiring; and
a radius of the first circle is larger than a radius of the second circle.

16. The semiconductor memory device according to claim 1, wherein
a distance between the first wiring and the first via-wiring is larger than a distance between the first gate electrode and the first via-wiring.

17. The semiconductor memory device according to claim 1, wherein
the memory portion is a capacitor.

18. The semiconductor memory device according to claim 1, wherein
the semiconductor layer includes an oxide semiconductor.

19. The semiconductor memory device according to claim 1, wherein
the semiconductor layer contains at least one element of gallium (Ga) and aluminum (Al), and contains indium (In), zinc (Zn), and oxygen (O).
